(19) United States
(12) Patent Application Publication
(10) Pub. No.: US 2025/0111829 A1
(43) Pub. Date: Apr. 3, 2025

(54) DISPLAY APPARATUS

(71) Applicant: Semiconductor Energy Laboratory Co., Ltd., Atsugi-shi (JP)

(72) Inventor: Atsushi UMEZAKI, Isehara (JP)

(21) Appl. No.: 18/893,076

(22) Filed: Sep. 23, 2024

(30) Foreign Application Priority Data
Sep. 29, 2023 (JP) 2023-169553

(51) Int. Cl. G09G 3/3266; G09G 3/3225; H10K 59/121

(52) U.S. Cl. CPC G09G 3/3266; G09G 3/3225; G09G 2300/0426; G09G 2310/0286; G09G 2310/08; G09G 2330/021; H10K 59/1213

(57) ABSTRACT

A novel display apparatus is provided. The display apparatus includes first to fifth p-channel transistors and an n-channel transistor. A gate of the fifth p-channel transistor and a gate of the n-channel transistor which operate at the same timing are connected to different nodes. A gate of the first p-channel transistor is directly connected to the gate of the n-channel transistor. The gate of the fifth p-channel transistor is electrically connected to the gate of the first p-channel transistor through a source and a drain of the third p-channel transistor.

### BACKGROUND OF THE INVENTION

### 1. Field of the Invention

One embodiment of the present invention relates to a display apparatus.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an image capturing device, a lighting device, an arithmetic device, a control device, a memory device, an input device, an output device, an input/output device, a signal processing unit, an arithmetic processing device, an electronic computer, an electronic device, a method of driving any of them, and a method of manufacturing any of them.

### 2. Description of the Related Art

As a result of recent technological innovation, commoditization of display apparatuses has progressed. In order to gain a competitive edge in the commoditization, higher-value added products have been required.

For example, a display apparatus using a transistor including an oxide semiconductor in a semiconductor layer where a channel formation region is formed (also referred to as an OS transistor) and a transistor including low-temperature polysilicon (LTPS) in a semiconductor layer where a channel formation region is formed (also referred to as an LTPS transistor) is known (see Patent Document 1). A display apparatus using an OS transistor and an LTPS transistor can be a display apparatus with high added value such as higher resolution, lower power consumption, higher switching speed, and/or a narrower bezel of a panel.

### REFERENCE

### Patent Document

[Patent Document 1] PCT International Publication No. 2021/053707

### SUMMARY OF THE INVENTION

Patent Document 1 discloses a structure in which the OS transistor and the LTPS transistor are used in a gate line driver circuit. Patent Document 1 discloses what is called a complementary circuit structure where an OS transistor is used as an n-channel transistor and an LTPS transistor is used as a p-channel transistor in part of the gate line driver circuit. In the case where an L-level signal is supplied to a gate in the complementary circuit structure, for example, the n-channel transistor is turned off and the p-channel transistor is turned on. A driver circuit including a complementary circuit structure is effective in reducing power consumption.

However, in the case where a signal that has not sufficiently decreased to an L level is supplied to the gate in the complementary circuit structure, for example, the n-channel transistor might not be turned off while the p-channel transistor is turned on. As a result, defects such as a malfunction of a driver circuit with the complementary circuit structure, an increase in power consumption, and/or deterioration of the transistor might be caused.

One object of one embodiment of the present invention is to provide a display apparatus capable of inhibiting an increase in power consumption. Another object of one embodiment of the present invention is to provide a display apparatus capable of reducing manufacturing cost. Another object of one embodiment of the present invention is to provide a highly reliable display apparatus. Another object of one embodiment of the present invention is to provide a novel display apparatus.

The objects listed above do not disturb the existence of other objects. In one embodiment of the present invention, there is no need to achieve all the objects listed above. Objects other than the objects listed above will be apparent from the descriptions of the specification, the drawings, the claims, and the like, and objects other than the objects listed above can be derived from the descriptions of the specification, the drawings, the claims, and the like.

One embodiment of the present invention is a display apparatus including a gate line driver circuit. A unit circuit included in the gate line driver circuit includes first to fifth p-channel transistors and an n-channel transistor. One of a source and a drain of the first p-channel transistor is electrically connected to a first clock signal line. One of a source and a drain of the second p-channel transistor is electrically connected to a first power supply line. The other of the source and the drain of the first p-channel transistor is electrically connected to the other of the source and the drain of the second p-channel transistor. A gate of the first p-channel transistor is electrically connected to one of a source and a drain of the third p-channel transistor. The gate of the first p-channel transistor is directly connected to a gate of the n-channel transistor. A gate of the third p-channel transistor is electrically connected to a second power supply line. The other of the source and the drain of the third p-channel transistor is electrically connected to one of a source and a drain of the fourth p-channel transistor. The other of the source and the drain of the third p-channel transistor is electrically connected to a gate of the fifth p-channel transistor. A gate of the fourth p-channel transistor is electrically connected to a second clock signal line. One of a source and a drain of the fifth p-channel transistor is electrically connected to the first power supply line. The other of the source and the drain of the fifth p-channel transistor is electrically connected to a gate of the second p-channel transistor. The other of the source and the drain of the fifth p-channel transistor is electrically connected to one of a source and a drain of the n-channel transistor. The other of the source and the drain of the n-channel transistor is electrically connected to the second power supply line.

In the display apparatus of one embodiment of the present invention, it is preferable that the n-channel transistor include a first semiconductor layer and the first semiconductor layer include an oxide semiconductor.

In the display apparatus of one embodiment of the present invention, it is preferable that the first to fifth p-channel transistors each include a second semiconductor layer and the second semiconductor layer contain silicon.

One embodiment of the present invention is a display apparatus including a gate line driver circuit. A unit circuit included in the gate line driver circuit includes first to seventh p-channel transistors and an n-channel transistor. One of a source and a drain of the first p-channel transistor is electrically connected to a first clock signal line. One of a source and a drain of the second p-channel transistor is electrically connected to a first power supply line. The other of the source and the drain of the first p-channel transistor is electrically connected to the other of the source and the drain of the second p-channel transistor. A gate of the first p-channel transistor is electrically connected to one of a source and a drain of the third p-channel transistor. The gate of the first p-channel transistor is directly connected to a gate of the n-channel transistor. A gate of the third p-channel transistor is electrically connected to a second power supply line. The other of the source and the drain of the third p-channel transistor is electrically connected to one of a source and a drain of the fourth p-channel transistor. The other of the source and the drain of the third p-channel transistor is electrically connected to one of a source and a drain of the sixth p-channel transistor. The other of the source and the drain of the third p-channel transistor is electrically connected to a gate of the fifth p-channel transistor. A gate of the fourth p-channel transistor is electrically connected to a second clock signal line. One of a source and a drain of the fifth p-channel transistor is electrically connected to the first power supply line. The other of the source and the drain of the fifth p-channel transistor is electrically connected to a gate of the second p-channel transistor. The other of the source and the drain of the fifth p-channel transistor is electrically connected to a gate of the seventh p-channel transistor. The other of the source and the drain of the fifth p-channel transistor is electrically connected to one of a source and a drain of the n-channel transistor. The other of the source and the drain of the n-channel transistor is electrically connected to the second power supply line. A gate of the sixth p-channel transistor is electrically connected to the first clock signal line. The other of the source and the drain of the sixth p-channel transistor is electrically connected to one of a source and a drain of the seventh p-channel transistor. The other of the source and the drain of the seventh p-channel transistor is electrically connected to the first power supply line.

In the display apparatus of one embodiment of the present invention, it is preferable that the n-channel transistor include a first semiconductor layer and the first semiconductor layer include an oxide semiconductor.

In the display apparatus of one embodiment of the present invention, it is preferable that the first to seventh p-channel transistors each include a second semiconductor layer and the second semiconductor layer contain silicon.

Note that other embodiments of the present invention will be shown in the following embodiments and the drawings.

One embodiment of the present invention can provide a display apparatus capable of inhibiting an increase in power consumption. Another embodiment of the present invention can provide a display apparatus capable of reducing manufacturing cost. Another embodiment of the present invention can provide a highly reliable display apparatus. Another embodiment of the present invention can provide a novel display apparatus.

The effects listed above do not disturb the existence of other effects. One embodiment of the present invention does not necessarily achieve all the effects listed above. Effects other than the effects listed above will be apparent from the descriptions of the specification, the drawings, the claims, and the like, and effects other than the effects listed above can be derived from the descriptions of the specification, the drawings, the claims, and the like.

### BRIEF DESCRIPTION OF THE DRAWINGS

FIGS. 1A and 1B are a block diagram and a circuit diagram illustrating a display apparatus.

FIGS. 2A and 2B are circuit diagrams illustrating a display apparatus.

FIG. 3 is a timing chart illustrating a display apparatus.

FIGS. 4A and 4B are circuit diagrams illustrating a display apparatus.

FIGS. 5A and 5B are circuit diagrams illustrating a display apparatus.

FIGS. 6A and 6B are circuit diagrams illustrating a display apparatus.

FIGS. 7A and 7B are a circuit diagram and a timing chart illustrating the operation of a display apparatus.

FIGS. 8A and 8B are circuit diagrams illustrating a display apparatus.

FIGS. 9A and 9B are circuit diagrams illustrating a display apparatus.

FIGS. 10A and 10B are circuit diagrams illustrating a display apparatus.

FIGS. 11A and 11B are circuit diagrams illustrating a display apparatus.

FIGS. 12A and 12B are circuit diagrams illustrating a display apparatus.

FIGS. 13A to 13C are circuit diagrams illustrating a display apparatus.

FIGS. 14A to 14C are circuit diagrams illustrating a display apparatus.

FIGS. 15A to 15C are circuit diagrams illustrating a display apparatus.

FIGS. 16A and 16B are circuit diagrams illustrating a display apparatus.

FIGS. 17A to 17C are circuit diagrams illustrating a display apparatus.

FIGS. 18A to 18C are circuit diagrams illustrating a display apparatus.

FIGS. 19A to 19C are circuit diagrams illustrating a display apparatus.

FIGS. 20A to 20C are circuit diagrams illustrating a display apparatus.

FIG. 21 is a timing chart illustrating a display apparatus.

FIGS. 22A and 22B are circuit diagrams illustrating a display apparatus.

FIGS. 23A and 23B are circuit diagrams illustrating a display apparatus.

FIGS. 24A and 24B are circuit diagrams illustrating a display apparatus.

FIGS. 25A and 25B are circuit diagrams illustrating a display apparatus.

FIG. 26 is a circuit diagram illustrating a display apparatus.

FIGS. 27A and 27B are circuit diagrams illustrating a display apparatus.

FIG. 28 is a perspective view illustrating a structure example of a display apparatus.

FIGS. 29A to 29C are cross-sectional views illustrating a structure example of a display apparatus.

FIGS. 30A and 30B are cross-sectional views illustrating a structure example of a display apparatus.

FIG. 31 is a plan view illustrating a structure example of a display apparatus.

FIGS. 32A and 32B are cross-sectional views illustrating a structure example of a display apparatus.

FIG. 33 is a plan view illustrating a structure example of a display apparatus.

FIG. 34 is a plan view illustrating a structure example of a display apparatus.

FIG. 35 is a plan view illustrating a structure example of a display apparatus.

FIG. 36 is a plan view illustrating a structure example of a display apparatus.

FIGS. 37A to 37D are circuit diagrams illustrating structure examples of a display apparatus.

FIGS. 38A to 38C are circuit diagrams illustrating a structure example of a display apparatus.

FIGS. 39A and 39B are diagrams illustrating an example of an electronic device.

FIGS. 40A to 40D are diagrams illustrating examples of electronic devices.

FIGS. 41A to 41G illustrate examples of electronic devices.

FIGS. 42A1 to 42A7 and FIGS. 42B1 to 42B6 are diagrams illustrating “connection” in this specification.

### DETAILED DESCRIPTION OF THE INVENTION

Hereinafter, embodiments will be described with reference to the drawings. However, embodiments can be implemented with various modes. Thus, it will be readily understood by those skilled in the art that the modes and details can be changed in various ways without departing from the spirit and scope thereof. Thus, one embodiment of the present invention should not be interpreted as being limited to the description of the embodiments.

In this specification and the like, the structure described in each embodiment can be combined with the structures described in the other embodiments as appropriate to constitute one embodiment of the present invention. In addition, in the case where a plurality of structures are described in one embodiment, the structures can be combined as appropriate to constitute one embodiment.

Note that in drawings illustrating the embodiments, the same portions or portions having similar functions are denoted by the same reference numerals in different drawings and the description of such portions is not repeated in some cases. In drawings, for example, the same hatching pattern is used for portions having similar functions, and the portions are not denoted by specific reference numerals in some cases. Moreover, some components may be omitted in a perspective view, a plan view, and the like for easy understanding of the diagrams. In drawings, some hidden lines and the like might be omitted. In drawings, hatching pattern or the like is omitted in some cases.

In the drawings, sizes, layer thicknesses, or regions are sometimes exaggerated for clarity. Thus, the drawings are not limited to the drawings with the illustrated size, aspect ratio, and the like, for example. Note that the drawings are schematic views showing ideal examples, and embodiments of the present invention are not limited to shapes or values shown in the drawings, for example. For example, in the actual manufacturing process, a layer, a resist mask, or the like might be unintentionally reduced in size by treatment such as etching, which is not illustrated in the drawings in some cases for easy understanding. For example, in the actual circuit operation, a fluctuation in voltage, current, or the like might be caused by noise, difference in timing, or the like, which is not illustrated in some cases for easy understanding.

In this specification, drawings, and the like, components of this invention are classified on the basis of the functions and shown as components independent of each other in some cases. However, in an actual circuit or the like, it may be difficult to separate components on the basis of the functions, so that one component may be associated with a plurality of functions or several components may be associated with one function. Accordingly, the components presented in this specification, drawings, and the like are not limited to the description thereof and can be described with another term as appropriate.

In this specification, drawings, and the like, when a plurality of components are denoted by the same reference numerals, and, particularly when they need to be distinguished from each other, an identification sign such as “A,” “b,” “_1,” “[n],” or “[m,n]” is sometimes added to the reference numerals, for example. When matters common to a plurality of components with identification signs are described or they do not need to be distinguished from each other, no identification sign is added in some cases.

### Embodiment 1

A display apparatus of one embodiment of the present invention will be described with reference to drawings. The display apparatus described in this embodiment includes a gate line driver circuit that outputs an output signal for selecting pixels row by row.

### <Structure Example of Display Apparatus>

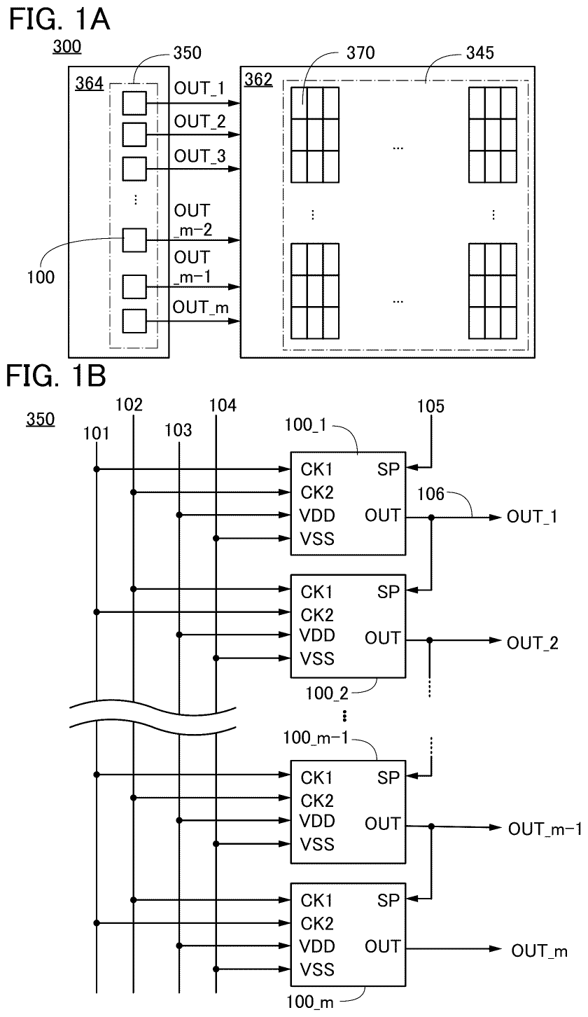

FIG. 1A is an example of a block diagram illustrating the display apparatus according to one embodiment of the present invention. FIG. 1B is an example of a circuit diagram illustrating a shift register that is included in the gate line driver circuit included in the display apparatus in FIG. 1A.

A display apparatus 300 illustrated in FIG. 1A includes a display portion 362 and a gate line driver circuit 364. The display portion 362 is provided with a pixel portion 345 including pixels 370 arranged in m rows and n columns (m and n are each an integer greater than or equal to 2). The gate line driver circuit 364 includes a shift register 350 that outputs output signals OUT_1 to OUT m for selecting the pixels 370 of each row provided in the pixel portion 345. The shift register 350 includes a plurality of unit circuits 100 that output output signals by supplying a clock signal and a start pulse signal. Note that the unit circuit is a circuit that outputs one row of output signals (also referred to as pulse signals or selection signals) in the shift register included in the gate line driver circuit. The unit circuit is referred to as a pulse signal output circuit or a selection signal output circuit in some cases.

The display portion 362 and the gate line driver circuit 364 include OS transistors and LTPS transistors. The OS transistor and the LTPS transistor can be thin film transistors (TFTs). The thin film transistor can be formed over a substrate having a light-transmitting property such as a glass substrate and thus size increase and cost reduction of the display apparatus 300 can be achieved. In addition, since the gate line driver circuit 364 and the display portion 362 can be formed over the same substrate, the bezel of the display apparatus can be narrowed and/or the number of components such as an external driver circuit can be reduced.

The display portion 362 and the gate line driver circuit 364 can have a circuit structure in which the OS transistor is an n-channel transistor and the LTPS transistor is a p-channel transistor. That is, the display portion 362 and the gate line driver circuit 364 can have a complementary circuit structure. In the complementary circuit, for example, an inverter circuit, supply of potentials with the same logic level to both gates of transistors can turn on one of the transistors and can turn off the other of the transistors, for example. In that case, the amount of current flowing between power supply lines can be reduced by providing an n-channel transistor and a p-channel transistor therebetween, whereby power consumption can be reduced. Note that a structure in which an LTPS transistor and an OS transistor are combined is referred to as LTPO in some cases.

The shift register 350 illustrated in FIG. 1B includes unit circuits 100_1 to 100_m (m is an integer greater than or equal to 2) as the plurality of unit circuits 100. The unit circuits 100_1 to 100_m are respectively connected to a wiring 101, a wiring 102, a power supply line 103, a power supply line 104, a wiring 105, and a wiring 106.

The wiring 101 transmits a clock signal CK1 to the unit circuits 100_1 to 100_m provided in each row. The wiring 102 transmits a clock signal CK2 to the unit circuits 100_1 to 100_m provided in each row. The wirings 101 and 102 are referred to as clock signal lines in some cases. In the unit circuits 100_1 to 100_m illustrated in FIG. 1B, terminals connected to the wirings 101 and 102 are denoted by CK1 and CK2.

The power supply line 103 transmits a power supply potential, e.g., a potential VDD, to the unit circuits 100_1 to 100_m provided in each row. The power supply line 104 transmits a power supply potential, e.g., a potential VSS, to the unit circuits 100_1 to 100_m provided in each row. In the unit circuits 100_1 to 100_m illustrated in FIG. 1B, a terminal connected to the power supply line 103 is denoted by VDD and a terminal connected to the power supply line 104 is denoted by VSS.

The wiring 105 transmits a control signal, e.g., a start pulse signal SP, to the unit circuit 100_1 provided in the first row. The wiring 105 is referred to as a signal line in some cases. In the unit circuit 100_1 illustrated in FIG. 1B, a terminal connected to the wiring 105 is denoted by SP. Note that in the unit circuits 100_2 to 100_m provided in the second and subsequent rows illustrated in FIG. 1B, an output signal outputted from the unit circuit 100 in the previous row functions as a control signal. Thus, a terminal connected to the wiring 106 in the previous row is denoted by SP.

The wiring 106 transmits output signals OUT_1 to OUT_m outputted from the unit circuits 100_1 to 100_m provided in each row. The wiring 106 is referred to as an output signal line in some cases. In the unit circuits 100_1 to 100_m illustrated in FIG. 1B, a terminal connected to the wiring 106 are denoted by OUT. As described above, in the unit circuits 100_1 to 100_m−1 illustrated in FIG. 1B, output signals OUT_1 to OUT_m−1 are control signals for the next row. That is, the wiring 106 that outputs the output signals OUT_1 to OUT_m−1 also functions as a signal line transmitting a control signal.

### <Structure Example of Unit Circuit 100>

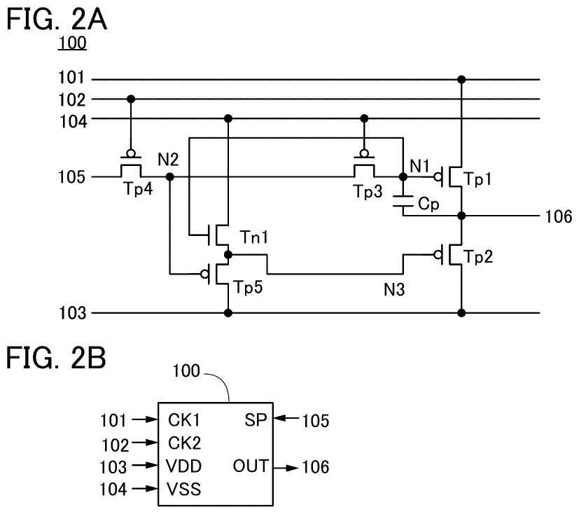

FIG. 2A is an example of a circuit diagram of the unit circuit 100 that can be used as the unit circuits 100_1 to 100_m in FIG. 1B. FIG. 2B is a circuit symbol representing the circuit diagram of the unit circuit 100 illustrated in FIG. 2A. The circuit diagram in FIG. 1B is illustrated using the circuit symbol in FIG. 2B.

The unit circuit 100 includes transistors Tp1 to Tp5, a transistor Tn1, and a capacitor Cp. The unit circuit 100 is connected to the wiring 101, the wiring 102, the power supply line 103, the power supply line 104, the wiring 105, and the wiring 106 described with reference to FIG. 1B.

One of a source and a drain of the transistor Tp1 is connected to the wiring 101. One of a source and a drain of the transistor Tp2 is connected to the power supply line 103. The other of the source and the drain of the transistor Tp1 is connected to the other of the source and the drain of the transistor Tp2. The other of the source and the drain of the transistor Tp1 is connected to the wiring 106. A gate of the transistor Tp1 is connected to one of a source and a drain of the transistor Tp3. The gate of the transistor Tp1 is connected to a gate of the transistor Tn1. One electrode of the capacitor Cp is connected to the other of the source and the drain of the transistor Tp1. The other electrode of the capacitor Cp is connected to the gate of the transistor Tp1. A gate of the transistor Tp3 is connected to the power supply line 104. The other of the source and the drain the transistor Tp3 is connected to one of a source and a drain of the transistor Tp4. The other of the source and the drain of the transistor Tp3 is connected to a gate of the transistor Tp5. The other of the source and the drain of the transistor Tp4 is connected to the wiring 105. A gate of the transistor Tp4 is connected to the wiring 102. One of a source and a drain of the transistor Tp5 is connected to the power supply line 103. The other of the source and the drain of the transistor Tp5 is connected to a gate of the transistor Tp2. The other of the source and the drain of the transistor Tp5 is connected to one of a source and a drain of the transistor Tn1. The other of the source and drain of the transistor Tn1 is connected to the power supply line 104.

Note that in the circuit diagram illustrated in FIG. 2A, nodes are denoted by reference numerals for easy understanding. In FIG. 2A, a node connected to the gate of the transistor Tn1 is denoted by a node N1, for example. In FIG. 2A, a node connected to the gate of the transistor Tp5 is denoted by a node N2. In FIG. 2A, a node connected to the gate of the transistor Tp2 is denoted by a node N3. Note that a node is an element (e.g., a wiring) that enables connection between elements included in a circuit. Thus, a “node connected to A” is a wiring that is connected to A and can be regarded as having the same potential as A.

The transistors Tp1 to Tp5 are p-channel transistors. A semiconductor layer including a channel formation region that is included in each of the transistors Tp1 to Tp5 contains silicon. Examples of silicon used in the semiconductor layers included in the transistors Tp1 to Tp5 include single crystal silicon, polycrystalline silicon, and amorphous silicon. In particular, an LTPS transistor including low-temperature polysilicon in its semiconductor layer is preferable. When the transistors Tp1 to Tp5 are LTPS transistors, the transistors can have high field-effect mobility and favorable frequency characteristics. The transistors Tp1 to Tp5 are referred to as first to fifth p-channel transistors in some cases.

Note that the transistor Tp1 and the transistor Tp2 that are connected to the wiring 106 outputting an output signal are respectively referred to as a pull-up transistor and a pull-down transistor in some cases. The transistor Tp3 having a function of making the potential or the voltage of the node N1 different from that of the node N2 is referred to as a potential adjustment transistor or a voltage adjustment transistor in some cases.

The transistor Tn1 is an n-channel transistor. An OS transistor including an oxide semiconductor in a semiconductor layer where a channel formation region is formed preferably used for the n-channel transistor.

An OS transistor features an extremely low off-state current because the band gap of the oxide semiconductor where the channel is formed is greater than or equal to 2 eV. The off-state current per micrometer of channel width of an OS transistor can be lower than or equal to 1×10⁻¹² A, lower than or equal to 1 aA (1×10⁻¹⁸ A), lower than or equal to 1 zA (1×10⁻²¹ A), or lower than or equal to 1 yA (1×10⁻²⁴ A) in a room-temperature environment. Thus, by providing the transistor Tn1 between the power supply lines 103 and 104 and turning off the transistor, the amount of current flowing between the power supply lines can be extremely small. Consequently, power consumption of the display apparatus can be reduced.

The off-state current of an OS transistor hardly increases even in a high temperature environment. Specifically, the off-state current hardly increases even at an environment temperature higher than or equal to room temperature and lower than or equal to 200° C. Furthermore, the on-state current of an OS transistor hardly decreases even in a high-temperature environment. Furthermore, even at an environment temperature higher than or equal to 125° C. and lower than or equal to 150° C., an OS transistor is capable of favorable switching operation owing to its high ratio of on-state current to off-state current. Accordingly, a semiconductor device including an OS transistor achieves stable operation and high reliability even in a high temperature environment. This means that the use of OS transistors as the transistors included in the gate line driver circuit 364 leads to the high reliability of the display apparatus.

An OS transistor has a high breakdown voltage between a source and a drain (also referred to as a drain breakdown voltage). Thus, the operation of an OS transistor is stable even when the OS transistor is driven with application of high voltage. For example, in the unit circuit 100, an OS transistor can be used as a transistor connected to a node to which high voltage is applied. Thus, the gate line driver circuit including an OS transistor can have improved reliability.

In addition, an OS transistor can be provided in a layer different from the layer of an LTPS transistor. In this case, a layer including an LTPS transistor and a layer including an OS transistor can be provided to overlap with each other. Such a structure can reduce the area occupied by the gate line driver circuit 364. In particular, in a display apparatus using an organic EL element, a plurality of kinds of gate line driver circuits are formed. Therefore, in the case where the gate line driver circuit 364 is used in the display apparatus including the organic EL element, the area where the gate line driver circuit 364 is placed can be small. In such a case, it is particularly preferable to make the area occupied by the gate line driver circuit 364 small by providing an OS transistor in a layer different from that of an LTPS transistor.

The OS transistor may have a structure including a gate or a structure including a gate and a back gate. It is particularly preferable that the OS transistor include a back gate. For example, in the case where the OS transistor includes a back gate, the threshold voltage of the OS transistor can be increased and decreased by application of a predetermined potential to the back gate of the OS transistor. Alternatively, when the back gate of the OS transistor is connected to the gate of the OS transistor, the on-state current of the OS transistor can be increased.

Note that transistors with a variety of structures can be used as the OS transistor and the LTPS transistor. For example, a planar type, a staggered type, a FIN-type, a Tri-Gate type, a top-gate type, a bottom-gate type, a dual-gate type (where gates are arranged at both sides of (e.g., above and below) the channel formation region), or the like can be used.

Note that the transistor Tn1 may be a transistor other than the OS transistor. An n-channel transistor having a higher breakdown voltage than the LTPS transistor used as the p-channel transistors can be used as the transistor Tn1. For example, an n-channel LTPS transistor can have improved breakdown voltage by increasing the channel length, the thickness of a gate insulating film, or the like, whereby the n-channel LTPS transistor can be applied to the transistor Tn1 as the n-channel transistor having a higher breakdown voltage than the LTPS transistor used as the p-channel transistors.

### <Operation Example of Unit Circuit 100>

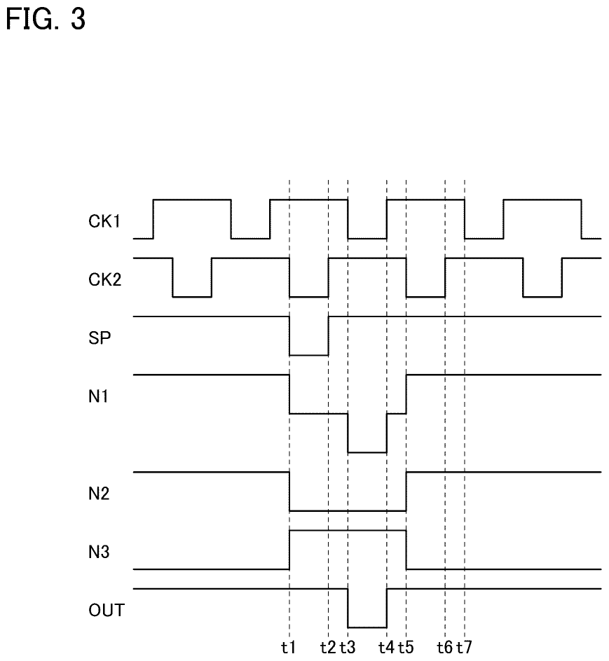

FIG. 3 is a timing chart illustrating the operation of the unit circuit 100 illustrated in the circuit diagram in FIG. 2A.

CK1 shown in FIG. 3 is a clock signal supplied to the wiring 101. CK2 shown in FIG. 3 is a clock signal supplied to the wiring 102. SP shown in FIG. 3 is a control signal supplied to the wiring 105. N1 to N3 shown in FIG. 3 represent changes in the potentials of the nodes N1 to N3. OUT shown in FIG. 3 is an output signal outputted to the wiring 106. In FIG. 3, time t1 to t7 are shown to describe the operation.

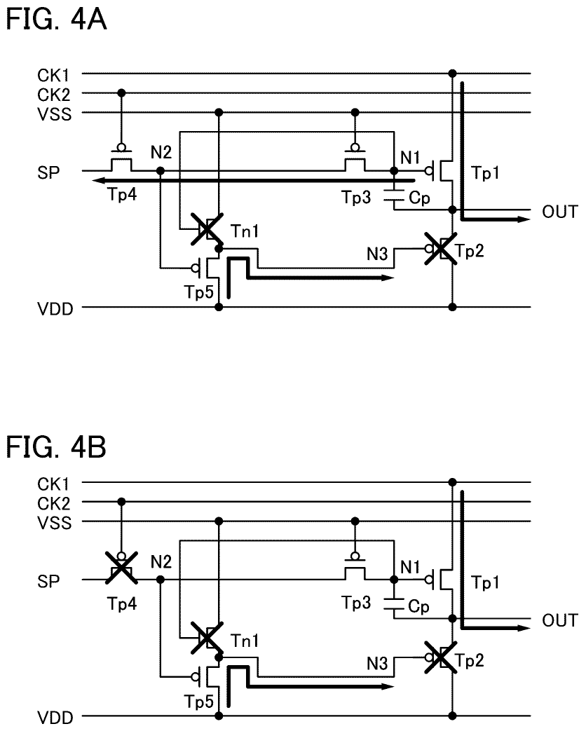

FIGS. 4A to 6B are circuit diagrams schematically illustrating operation at time t1 to t7 illustrated in FIG. 3. In FIGS. 4A to 6B, a cross overlaps with a circuit symbol of a transistor that is in an off state. In addition, in FIGS. 4A to 6B, current flowing during the on state of the transistor is indicated by a bold arrow.

Note that in the following description, the power supply line 103 is regarded as being at the potential VDD (hereinafter referred to as VDD) and the power supply line 104 is regarded as being at the potential VSS (hereinafter referred to as VSS). In the p-channel transistor, when the logic level of a signal applied to the gate is an L level (low level), the transistor is turned on, and when the logic level of a signal applied to the gate is an H level (high level), the transistor is turned off. In the n-channel transistor, when the logic level of a signal applied to the gate is the H level, the transistor is turned on and when the logic level of a signal applied to the gate is the L level, the transistor is turned off. Thus, the logic level at which a transistor is turned on is referred to as an on level, and the logic level at which a transistor is turned off is referred to as an off level in some cases. Note that the H level refers to a potential based on the high potential side of a control signal and a clock signal or a potential based on VDD. The L level refers to a potential based on the low potential side of the control signal and the clock signal or a potential based on VSS.

FIG. 4A is a diagram illustrating operation in a period between time t1 and time t2 illustrated in FIG. 3. The transistors Tp1 and Tp3 to Tp5 are turned on and the transistors Tp2 and Tn1 are turned off by CK1, CK2, SP, VDD, and VSS. OUT becomes an H-level potential of CK1. N1 and N2 become the L level of SP. N3 becomes VDD, that is, the H level.

FIG. 4B is a diagram illustrating operation in a period between time t2 and time t3 illustrated in FIG. 3. The transistors Tp1, Tp3, and Tp5 are turned on and the transistors Tp2, Tp4, and Tn1 are turned off by CK1, CK2, SP, VDD, and VSS. OUT becomes an H-level potential of CK1. Since the transistor Tp4 is turned off, N1 and N2 are brought into an electrically floating state (floating). Thus, the L level of SP is retained in N1 and N2. N3 remains at VDD, i.e., the H level.

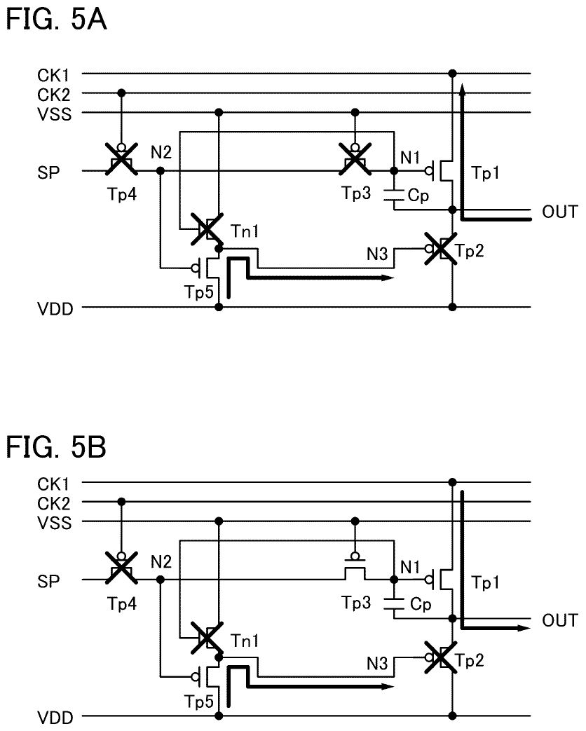

FIG. 5A is a diagram illustrating operation in a period between time t3 and time t4 illustrated in FIG. 3. The transistors Tp1 and Tp5 are turned on and the transistors Tp2 to Tp4 and Tn1 are turned off by CK1, CK2, SP, VDD, and VSS.

In the period between time t3 and time t4, the transistor Tp4 is turned off, so that N1 and N2 are floating. Since the potential difference between electrodes at both ends of the capacitor Cp is maintained, the potential of N1 changes along with the change in the potential of OUT. Specifically, as CK1 changes from the H level to the L level, the potentials of OUT and N1 also decrease. As the potential of N1 decreases, the gate-source voltage (Vgs) of the transistor Tp3 becomes higher than or equal to the threshold voltage (Vth<0), so that the transistor Tp3 is turned off. N2 becomes VSS−Vth, which is a potential lower than VSS by the threshold voltage (Vth) of the transistor Tp3, and N1 becomes a potential lower than VSS−Vth. The potentials of the signals with the same logic level, e.g., the L-level in N1 and N2 can be made different with the transistor Tp3, which is a potential adjustment transistor.

When N1 becomes a potential lower than VSS−Vth, OUT can be decreased to VSS. N3 remains at VDD, i.e., the H level.

In one embodiment of the present invention, in order to control the on state of the transistor Tn1 and the off state of the transistor Tp5 that operate at the same logic level with different potentials, the gate of the transistor Tn1 is connected to the node N1 and the gate of the transistor Tp5 is connected to the node N2.

The potential of the node N1 is lower than the potential of the node N2. The potential of the node N1 is set to an off-level signal of the transistor Tn1 which is an n-channel transistor, so that the transistor Tn1 can be turned off more reliably. The potential of the node N1 is lower than VSS and thus deterioration and dielectric breakdown of the transistor might be induced; however, the deterioration and dielectric breakdown of the transistor can be prevented owing to the transistor Tn1 that is an OS transistor.

VSS−Vth of the node N2 is higher than the potential of the node N1. The potential of the node N2 is set to an on-level signal of the transistor Tp5 which is a p-channel transistor, so that the transistor can be turned on without deterioration and dielectric breakdown thereof. Since the potential of the node N2 is lower than the potential of the node N1, deterioration and/or dielectric breakdown of the transistors Tp3 and Tp4 which are the other transistors connected to the node N2 can be prevented.

FIG. 5B is a diagram illustrating operation in a period between time t4 and time t5 illustrated in FIG. 3. The transistors Tp1, Tp3, and Tp5 are turned on and the transistors Tp2, Tp4, and Tn1 are turned off by CK1, CK2, SP, VDD, and VSS. OUT becomes an H-level potential of CK1. Since the transistor Tp4 is turned off, N1 and N2 are brought into a floating state. Thus, the L level of SP is retained in N1 and N2. N3 remains at VDD, i.e., the H level.

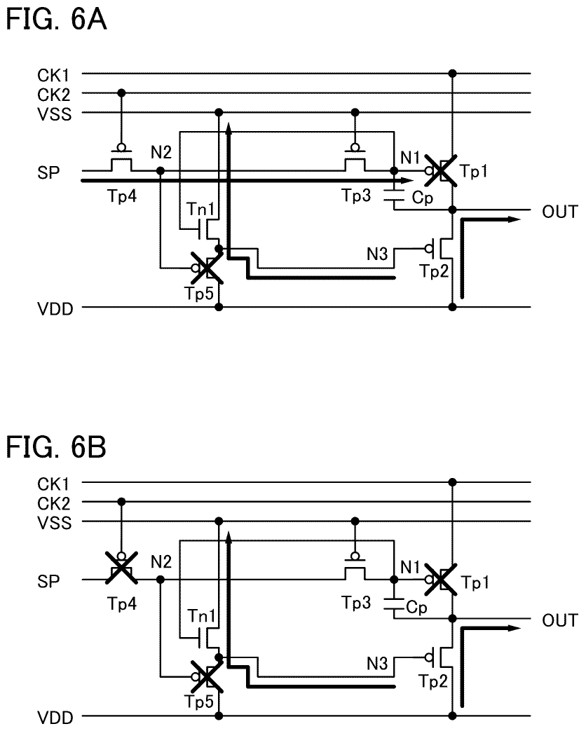

FIG. 6A is a diagram illustrating operation in a period between time t5 and time t6 illustrated in FIG. 3. The transistors Tp2 to Tp4 and Tn1 is turned on and the transistors Tp1 and Tp5 is turned on by CK1, CK2, SP, VDD, and VSS. OUT becomes VDD. N1 and N2 each become an H-level potential of SP. N3 becomes VSS, that is, the L level.

FIG. 6B is a diagram illustrating operation in a period between time t6 and time t7 illustrated in FIG. 3. The transistors Tp2, Tp3, and Tn1 are turned on and the transistors Tp1, Tp4, and Tp5 are turned off by CK1, CK2, SP, VDD, and VSS. OUT remains at VDD. Since the transistor Tp4 is turned off, N1 and N2 are brought into a floating state. Thus, the H level of SP is retained in N1 and N2. N3 remains at VSS, i.e., the L level.

### <Structure Example of Unit Circuit 100A>

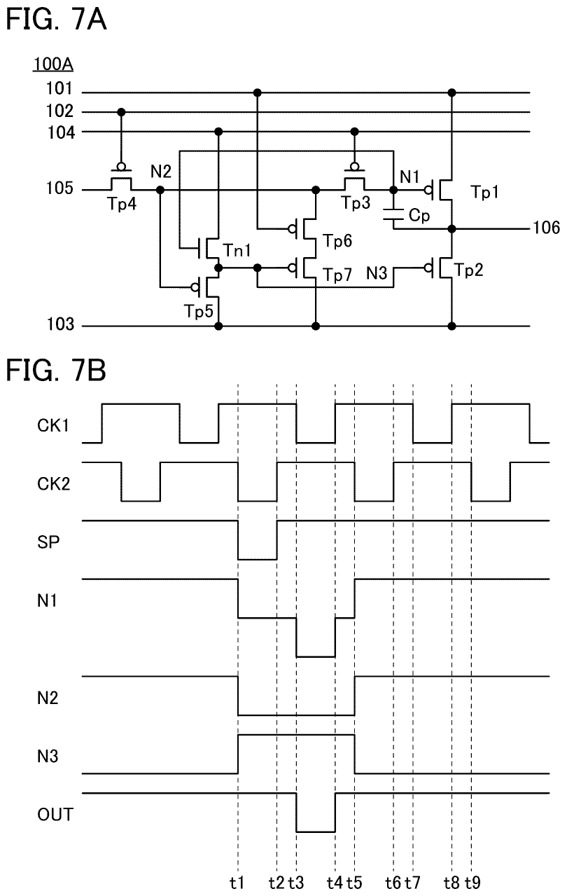

FIG. 7A is a circuit diagram of a unit circuit 100A having a structure different from that of the unit circuit 100 described with reference to FIG. 2A. In the description of FIG. 7A, the above description of FIG. 2A is referred to for the same structure, and the description thereof is omitted in some cases.

The unit circuit 100A includes the transistors Tp1 to Tp7, the transistor Tn1, and the capacitor Cp. The unit circuit 100A can be used as the unit circuits 100_1 to 100_m included in the shift register 350 illustrated in FIG. 1B. The unit circuit 100A is connected to the wiring 101, the wiring 102, the power supply line 103, the power supply line 104, the wiring 105, and the wiring 106.

One of the source and the drain of the transistor Tp1 is connected to the wiring 101. One of the source and the drain of the transistor Tp2 is connected to the power supply line 103. The other of the source and the drain of the transistor Tp1 is connected to the other of the source and the drain of the transistor Tp2. The other of the source and the drain of the transistor Tp1 is connected to the wiring 106. The gate of the transistor Tp1 is connected to one of the source and the drain of the transistor Tp3. The gate of the transistor Tp1 is connected to the gate of the transistor Tn1. The one electrode of the capacitor Cp is connected to the other of the source and the drain of the transistor Tp1. The other electrode of the capacitor Cp is connected to the gate of the transistor Tp1. The gate of the transistor Tp3 is connected to the power supply line 104. The other of the source and the drain the transistor Tp3 is connected to one of the source and the drain of the transistor Tp4. The other of the source and the drain of the transistor Tp3 is connected to one of a source and a drain of a transistor Tp6. The other of the source and the drain of the transistor Tp3 is connected to the gate of the transistor Tp5. The other of the source and the drain of the transistor Tp4 is connected to the wiring 105. The gate of the transistor Tp4 is connected to the wiring 102. The one of the source and the drain of the transistor Tp5 is connected to the power supply line 103. The other of the source and the drain of the transistor Tp5 is connected to the gate of the transistor Tp2. The other of the source and the drain of the transistor Tp5 is connected to a gate of the transistor Tp7. The other of the source and the drain of the transistor Tp5 is connected to one of the source and the drain of the transistor Tn1. The other of the source and drain of the transistor Tn1 is connected to the power supply line 104. A gate of the transistor Tp6 is connected to the wiring 101. The other of the source and the drain the transistor Tp6 is connected to one of a source and a drain of the transistor Tp7. The other of the source and the drain of the transistor Tp7 is connected to the power supply line 103.

The transistors Tp1 to Tp7 are p-channel transistors. The semiconductor layer including the channel formation region included in each of the transistors Tp1 to Tp7 contains silicon. Examples of silicon used for the semiconductor layers included in the transistors Tp1 to Tp7 include single crystal silicon, polycrystalline silicon, and amorphous silicon. In particular, an LTPS transistor including low-temperature polysilicon in its semiconductor layer is preferable. When the transistors Tp1 to Tp7 are LTPS transistors, the transistors can have high field-effect mobility and favorable frequency characteristics. The transistors Tp1 to Tp7 are sometimes referred to as first to seventh p-channel transistors.

The transistor Tn1 is an n-channel transistor. An OS transistor including an oxide semiconductor in a semiconductor layer including a channel formation region is preferably used for the n-channel transistor.

### <Operation Example of Unit Circuit 100A>

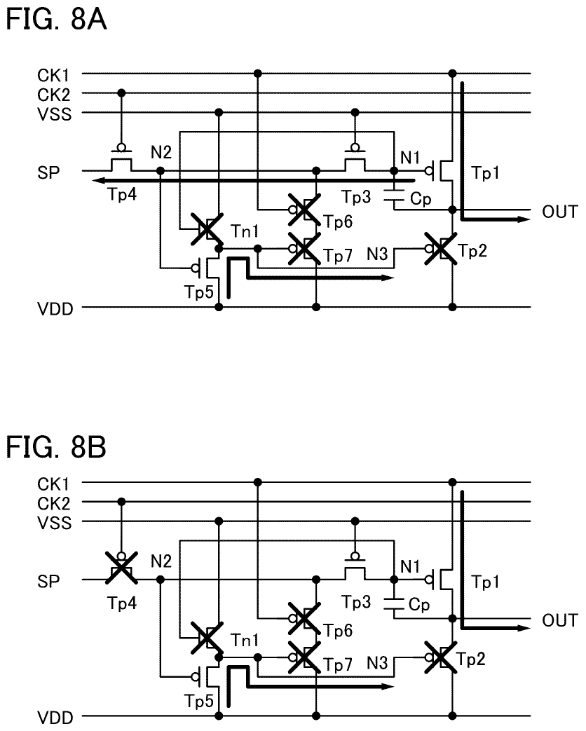

FIG. 7B is a timing chart illustrating operation of the unit circuit 100A illustrated in the circuit diagram in FIG. 7A. FIGS. 8A to 11B are circuit diagrams schematically illustrating operation at the time t1 to t9 illustrated in FIG. 7B. In FIG. 7B, time t1 to t9 are denoted to describe the operation. Note that in the description of FIG. 7B and FIGS. 8A to 11B, the above descriptions of FIG. 3 and FIGS. 4A to 6B are referred to for the same structures, and the description thereof is omitted in some cases.

FIG. 8A is a diagram illustrating operation in the period between time t1 and time t2 illustrated in FIG. 7B. The transistors Tp1 and Tp3 to Tp5 are turned on and the transistors Tp2, Tp6, Tp7 and Tn1 are turned off by CK1, CK2, SP, VDD, and VSS. OUT becomes an H-level potential of CK1. N1 and N2 become the L level of SP. N3 becomes VDD, that is, the H level.

FIG. 8B is a diagram illustrating operation in the period between time t2 and time t3 illustrated in FIG. 7B. The transistors Tp1, Tp3, and Tp5 are turned on and the transistors Tp2, Tp4, Tp6, Tp7, and Tn1 are turned off by CK1, CK2, SP, VDD, and VSS. OUT becomes an H-level potential of CK1. Since the transistors Tp4, Tp6, and Tp7 are turned off, N1 and N2 are brought into a floating state. Thus, the L level of SP is retained in N1 and N2. N3 remains at VDD, i.e., the H level.

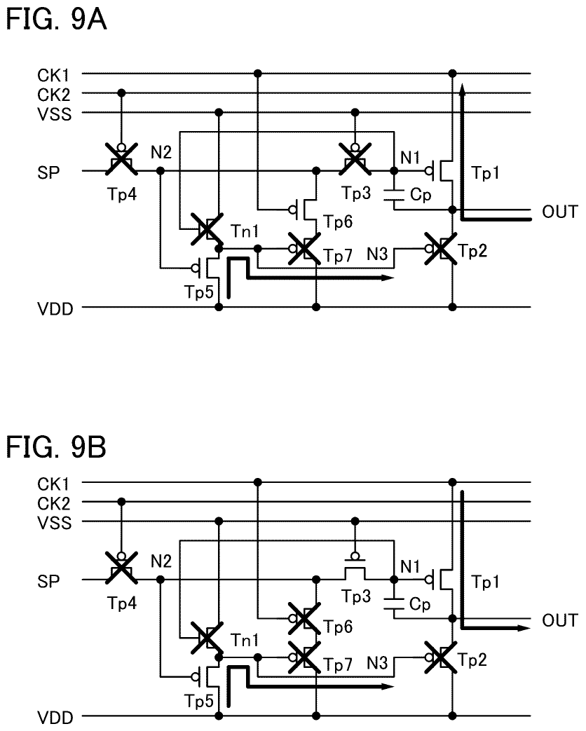

FIG. 9A is a diagram illustrating operation in the period between time t3 and time t4 illustrated in FIG. 7B. The transistors Tp1, Tp5, and Tp6 are turned on and the transistors Tp2 to Tp4, Tp7, and Tn1 are turned off by CK1, CK2, SP, VDD, and VSS.

In the period between time t3 and time t4, the transistors Tp4 and Tp7 are turned off, so that N1 and N2 are floating. Since the potential difference between the electrodes at both ends of the capacitor Cp is maintained, the potential of N1 changes along with the change in OUT. Specifically, as CK1 changes from the H level to the L level, the potential of N1 also decreases. As the potential of N1 decreases, the gate-source voltage (Vgs) of the transistor Tp3 becomes higher than or equal to the threshold voltage (Vth<0), so that the transistor Tp3 is turned off. N2 becomes VSS−Vth, which is a potential lower than VSS by the threshold voltage (Vth) of the transistor Tp3, and N1 becomes a potential lower than VSS−Vth. The potentials of the signals with the same logic level, e.g., the L-level in N1 and N2 can be made different with the transistor Tp3, which is a potential adjustment transistor.

When N1 becomes a potential lower than VSS−Vth, OUT can be decreased to VSS. N3 remains at VDD, i.e., the H level.

In one embodiment of the present invention, in order to control the on state of the transistor Tn1 and the off state of the transistor Tp5 that operate at the same logic level with different potentials, the gate of the transistor Tn1 is connected to the node N1 and the gate of the transistor Tp5 is connected to the node N2.

The potential of the node N1 is lower than the potential of the node N2. The potential of the node N1 is set to an off-level signal of the transistor Tn1 which is an n-channel transistor, so that the transistor Tn1 can be turned off more reliably. The potential of the node N1 is lower than VSS and thus deterioration and dielectric breakdown of the transistor might be induced; however, the deterioration and dielectric breakdown of the transistor can be prevented owing to the transistor Tn1 that is an OS transistor.

VSS−Vth of the node N2 is higher than the potential of the node N1. The potential of the node N2 is set to an on-level signal of the transistor Tp5 which is a p-channel transistor, so that the transistor can be turned on without deterioration and dielectric breakdown thereof. Since the potential of the node N2 is lower than the potential of the node N1, deterioration and/or dielectric breakdown of the transistors Tp3 and Tp4 which are other transistors connected to the node N2 can be prevented.

FIG. 9B is a diagram illustrating operation in the period between time t4 and time t5 illustrated in FIG. 7B. The transistors Tp1, Tp3, and Tp5 are turned on and the transistors Tp2, Tp4, Tp6, Tp7, and Tn1 are turned off by CK1, CK2, SP, VDD, and VSS. OUT becomes an H-level potential of CK1. Since the transistors Tp4, Tp6, and Tp7 are turned off, N1 and N2 are brought into a floating state. Thus, the L level of SP is retained in N1 and N2. N3 remains at VDD, i.e., the H level.

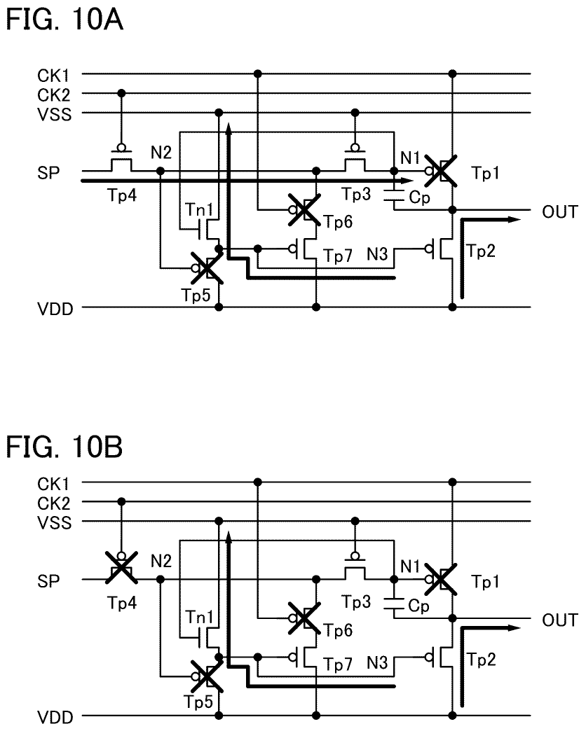

FIG. 10A is a diagram illustrating operation in the period between time t5 and time t6 illustrated in FIG. 7B. The transistors Tp2 to Tp4, Tp7, and Tn1 are turned on and the transistors Tp1, Tp5, and Tp6 are turned off by CK1, CK2, SP, VDD, and VSS. OUT becomes VDD. N1 and N2 each become an H-level potential of SP. N3 becomes VSS, that is, the L level.

FIG. 10B is a diagram illustrating operation in the period between time t6 and time t7 illustrated in FIG. 7B. The transistors Tp2, Tp3, Tp7, and Tn1 are turned on and the transistors Tp1, Tp4, Tp5, and Tp6 are turned off by CK1, CK2, SP, VDD, and VSS. OUT remains at VDD. Since the transistors Tp4 and Tp6 are turned off, N1 and N2 are brought into a floating state. Thus, the H level of SP is retained in N1 and N2. N3 remains VSS, i.e., the L level.

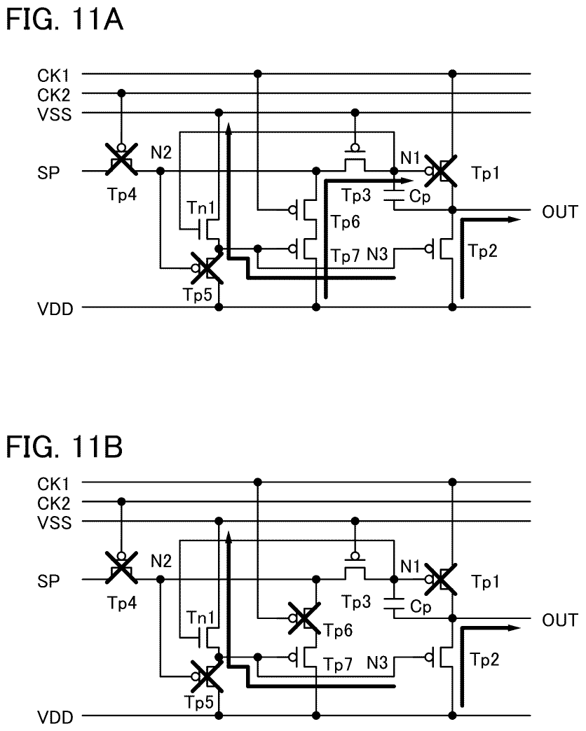

FIG. 11A is a diagram illustrating operation in a period between time t7 and time t8 illustrated in FIG. 7B. The transistors Tp2, Tp3, Tp6, and Tp7 and the transistors Tn1 are turned on and the transistors Tp1, Tp4, and Tp5 are turned off by CK1, CK2, SP, VDD, and VSS. OUT remains at VDD. Since the transistors Tp6 and Tp7 are turned on, N1 and N2 become VDD, i.e., the H level. With this structure, the H level is periodically supplied to N1 and N2, which enables the continuous off state of the transistor Tp1 that is a pull-up transistor. N3 remains at VSS, i.e., the L level.

FIG. 11B is a diagram illustrating operation in a period between time t8 and time t9 illustrated in FIG. 7B. The transistors Tp2, Tp3, Tp7, and Tn1 are turned on and the transistors Tp1, Tp4, Tp5, and Tp6 are turned off by CK1, CK2, SP, VDD, and VSS. OUT remains at VDD. Since the transistors Tp4 and Tp6 are turned off, N1 and N2 are brought into a floating state. Thus, VDD, i.e., the H level, is retained in N1 and N2. N3 remains at VSS, i.e., the L level.

### Modification Example 1 of Unit Circuit 100A

Modification examples of the above-described unit circuit 100A is described below. In the description of the modification examples of the unit circuit 100A below, the above description of the unit circuit 100A in FIG. 7A is referred to for the same structure, and the description thereof is omitted in some cases.

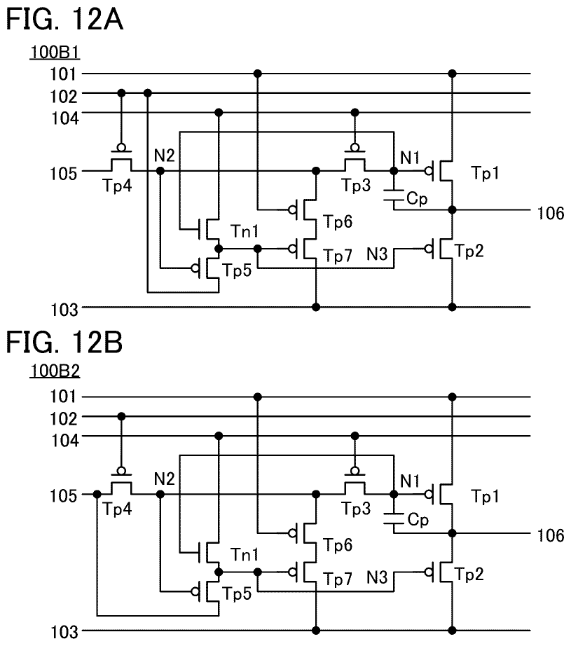

In the unit circuit 100A, wirings or transistors to which the transistor Tp5 is connected can have structures in FIGS. 12A to 14C.

A unit circuit 100B1 illustrated in FIG. 12A has the structure where one of the source and the drain of the transistor Tp5 is connected to the wiring 102 in the structure of the unit circuit 100A. With this structure, the number of transistors connected to the power supply line 103 can be reduced, so that a load on the power supply line 103 can be reduced. Furthermore, the potential of one of the source and the drain of the transistor Tp5 can be changed, so that deterioration of the transistor Tp5 can be inhibited. In a period between time t1 and time 2, the node N3 is set to the L level, so that the transistors Tp2 and Tp7 can be turned on. When the transistor Tp2 is turned on, VDD can be outputted to OUT. Thus, OUT is easily set to an H-level potential.

A unit circuit 100B2 illustrated in FIG. 12B has a structure where one of the source and the drain of the transistor Tp5 is connected to the wiring 105 in the structure of the unit circuit 100A. With this structure, the number of transistors connected to the power supply line 103 can be reduced, so that the load on the power supply line 103 can be reduced. Furthermore, the potential of one of the source and the drain of the transistor Tp5 can be changed, so that deterioration of the transistor Tp5 can be inhibited. In the period between time t1 and time 2, the node N3 can be set to the L level, so that the transistors Tp2 and Tp7 can be turned on. When the transistor Tp2 is turned on, VDD can be outputted to OUT. Thus, OUT is easily set to an H-level potential.

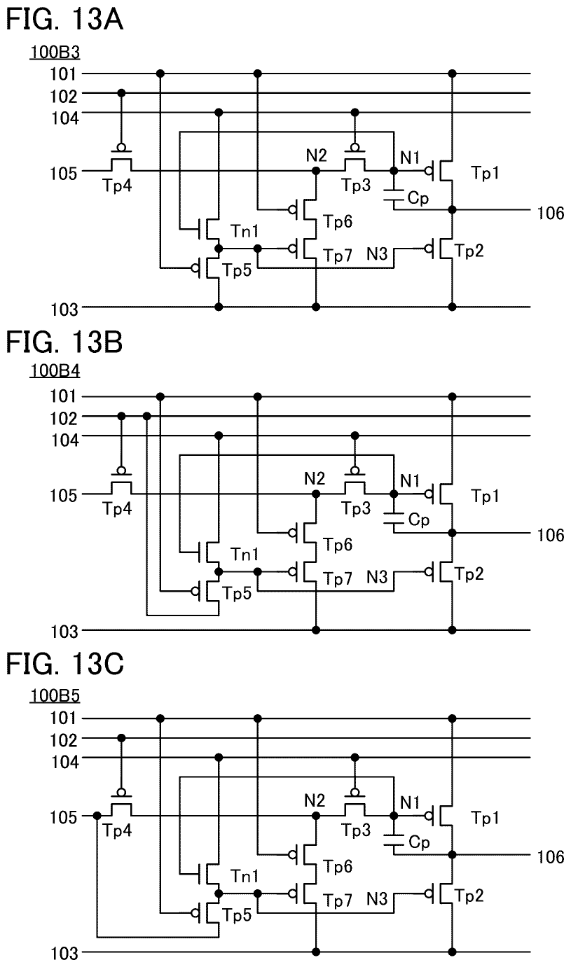

A unit circuit 100B3 illustrated in FIG. 13A has a structure where the gate of the transistor Tp5 is connected to the wiring 101 in the structure of the unit circuit 100A. With this structure, the number of transistors connected to the node N2 can be reduced, so that the parasitic capacitance of the node N2 can be reduced.

A unit circuit 100B4 illustrated in FIG. 13B has a structure where the gate of the transistor Tp5 is connected to the wiring 101 and the one of the source and the drain of the transistor Tp5 is connected to the wiring 102 in the structure of the unit circuit 100A. This structure corresponds to a structure where the modification examples illustrated in the unit circuit 100B1 and the unit circuit 100B3 are combined. In this manner, one embodiment of the present invention can have a structure where the above-described modification examples are combined. With this structure, the parasitic capacitance of the node N2 can be reduced as well as reducing the load of the power supply line 103.

A unit circuit 100B5 illustrated in FIG. 13C has a structure where the gate of the transistor Tp5 is connected to the wiring 101 and the one of the source and the drain of the transistor Tp5 is connected to the wiring 105 in the structure of the unit circuit 100A. This structure corresponds to a structure where the modification examples illustrated in the unit circuit 100B2 and the unit circuit 100B3 are combined. In this manner, one embodiment of the present invention can have a structure where the above-described modification examples are combined. With this structure, the parasitic capacitance of the node N2 can be reduced as well as reducing the load of the power supply line 103. Furthermore, the potential of one of the source and the drain of the transistor Tp5 can be changed, so that deterioration of the transistor Tp5 can be inhibited.

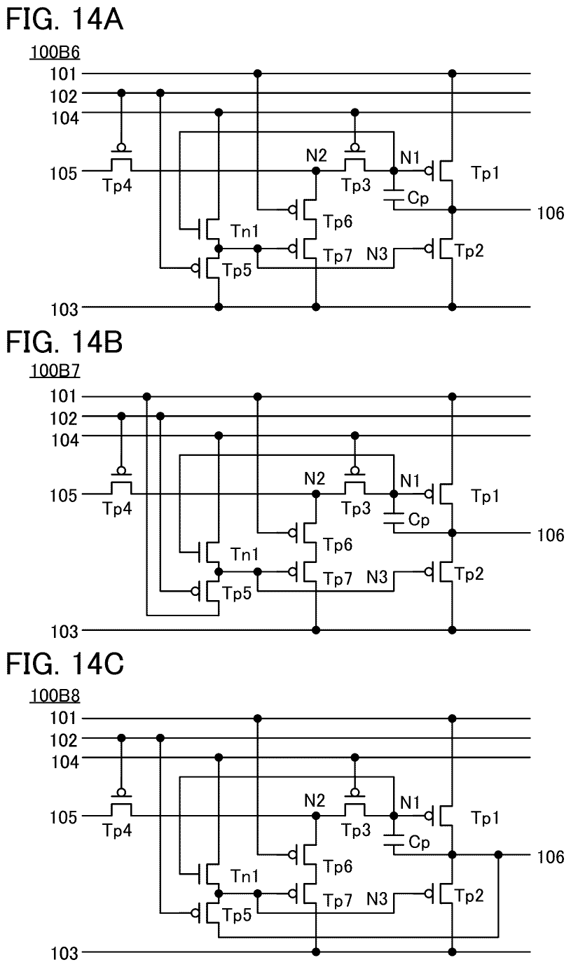

A unit circuit 100B6 illustrated in FIG. 14A has a structure where the gate of the transistor Tp5 is connected to the wiring 102 in the structure of the unit circuit 100A. With this structure, the number of transistors connected to the node N2 can be reduced, so that the parasitic capacitance of the node N2 can be reduced.

A unit circuit 100B7 illustrated in FIG. 14B has a structure where the gate of the transistor Tp5 is connected to the wiring 102 and the one of the source and the drain of the transistor Tp5 is connected to the wiring 101 in the structure of the unit circuit 100A. This structure corresponds to a structure where the modification examples illustrated in the unit circuit 100B1 and the unit circuit 100B6 are combined. In this manner, one embodiment of the present invention can have a structure where the above-described modification examples are combined. With this structure, the parasitic capacitance of the node N2 can be reduced as well as reducing the load of the power supply line 103.

A unit circuit 100B8 illustrated in FIG. 14C has a structure where the gate of the transistor Tp5 is connected to the wiring 102 and the one of the source and the drain of the transistor Tp5 is connected to the wiring 106 in the structure of the unit circuit 100A. This structure corresponds to a structure where the modification examples illustrated in the unit circuit 100B2 and the unit circuit 100B6 are combined. In this manner, one embodiment of the present invention can have a structure where the above-described modification examples are combined. With this structure, the parasitic capacitance of the node N2 can be reduced as well as reducing the load of the power supply line 103.

### Modification Example 2 of Unit Circuit 100A

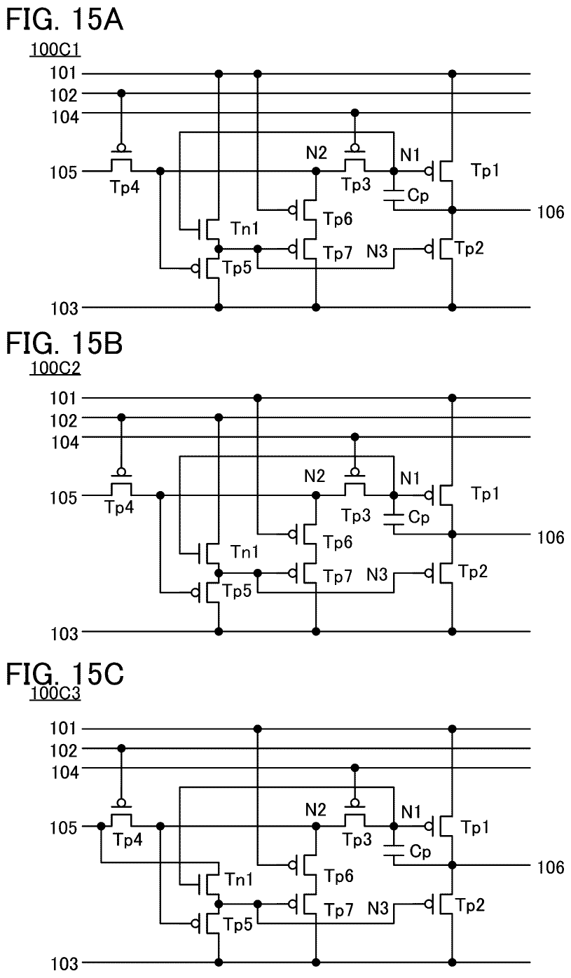

In the unit circuit 100A, wirings or transistors to which the transistor Tn1 is connected can have structures in FIGS. 15A to 15C.

A unit circuit 100C1 illustrated in FIG. 15A has a structure where the other of the source and the drain of the transistor Tn1 is connected to the wiring 101 in the structure of the unit circuit 100A. With this structure, the number of transistors connected to the power supply line 104 can be reduced, so that a load on the power supply line 104 can be reduced. Furthermore, the potential of the other of the source and the drain of the transistor Tn1 can be changed, so that deterioration of the transistor Tn1 can be inhibited.

A unit circuit 100C2 illustrated in FIG. 15B has a structure where the other of the source and the drain of the transistor Tn1 is connected to the wiring 102 in the structure of the unit circuit 100A. With this structure, the number of transistors connected to the power supply line 104 can be reduced, so that the load on the power supply line 104 can be reduced. Furthermore, the potential of the other of the source and the drain of the transistor Tn1 can be changed, so that deterioration of the transistor Tn1 can be inhibited. Furthermore, in the period between time t3 and time t4, the other of the source and the drain of the transistor Tn1 can be set to the H level, so that the transistor Tn1 can be easily turned off. At this time, a high voltage is applied to the transistor Tn1; however, the use of an OS transistor as the transistor Tn1 can prevent deterioration and dielectric breakdown of the transistor Tn1.

A unit circuit 100C3 illustrated in FIG. 15C has a structure where the other of the source and the drain of the transistor Tn1 is connected to the wiring 105 in the structure of the unit circuit 100A. With this structure, the number of transistors connected to the power supply line 104 can be reduced, so that the load on the power supply line 104 can be reduced. Furthermore, the potential of the other of the source and the drain of the transistor Tn1 can be changed, so that deterioration of the transistor Tn1 can be inhibited.

The modification examples shown in the unit circuits 100C1 to 100C3 can be combined with the above-described modification examples of the unit circuits 100B1 to 100B8. With this structure, the load on the power supply line 103 can be reduced and/or the parasitic capacitance of the node N2 can be reduced.

### Modification Example 3 of Unit Circuit 100A

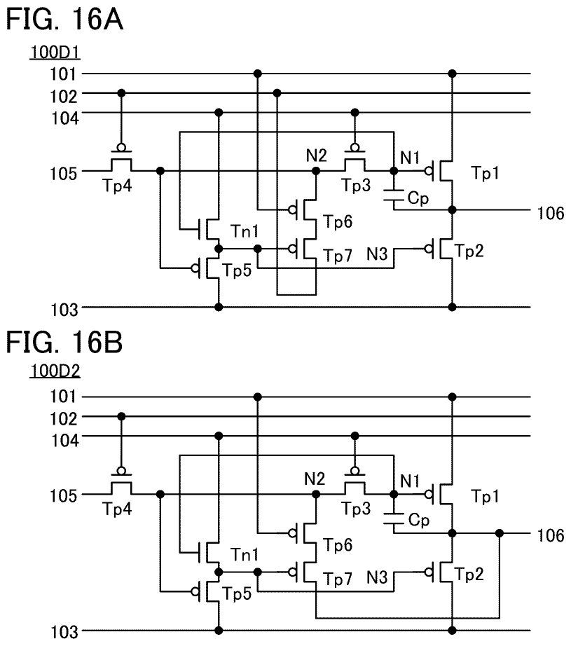

In the unit circuit 100A, wirings or transistors to which the transistors Tp6 and Tp7 are connected can have structures in FIGS. 16A to 18C.

A unit circuit 100D1 illustrated in FIG. 16A has a structure where the other of the source and the drain of the transistor Tp7 is connected to the wiring 102 in the structure of the unit circuit 100A. With this structure, the number of transistors connected to the power supply line 103 can be reduced, so that the load on the power supply line 103 can be reduced. Furthermore, the potential of the other of the source and the drain of the transistor Tp7 can be changed, so that deterioration of the transistor Tp7 can be inhibited.

A unit circuit 100D2 illustrated in FIG. 16B has a structure where the other of the source and the drain of the transistor Tp7 is connected to the wiring 106 in the structure of the unit circuit 100A. With this structure, the number of transistors connected to the power supply line 103 can be reduced, so that the load on the power supply line 103 can be reduced. Furthermore, the potential of the other of the source and the drain of the transistor Tp7 can be changed, so that deterioration of the transistor Tp7 can be inhibited.

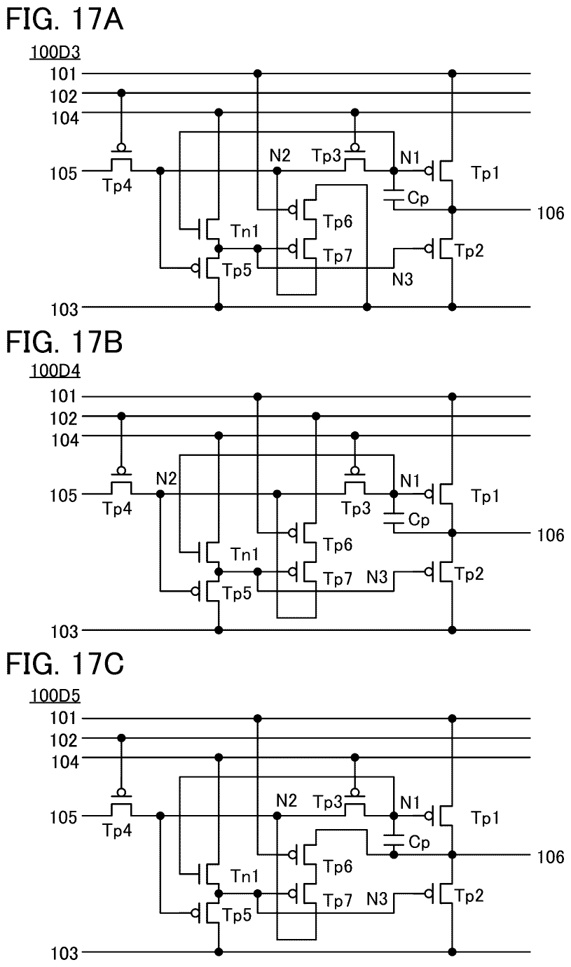

A unit circuit 100D3 illustrated in FIG. 17A has a structure where the other of the source and the drain of the transistor Tp7 is connected to the node N2 and the one of the source and the drain of the transistor Tp6 is connected to the power supply line 103 in the structure of the unit circuit 100A. With this structure, the transistor Tp6 can be connected to the node N2 through the transistor Tp7; thus, the influence of noise of the clock signal CK1 supplied to the gate of the transistor Tp6 on the node N2 can be reduced. Furthermore, the potential of one of the source and the drain of the transistor Tp6 can be changed, so that deterioration of the transistor Tp6 can be inhibited.

A unit circuit 100D4 illustrated in FIG. 17B has a structure where the other of the source and the drain of the transistor Tp7 is connected to the node N2 and the one of the source and the drain of the transistor Tp6 is connected to the wiring 102 in the structure of the unit circuit 100A. With this structure, the transistor Tp6 can be connected to the node N2 through the transistor Tp7; thus, the influence of noise of the clock signal CK1 supplied to the gate of the transistor Tp6 on the node N2 can be reduced. Furthermore, the potential of one of the source and the drain of the transistor Tp6 can be changed, so that deterioration of the transistor Tp6 can be inhibited.

A unit circuit 100D5 illustrated in FIG. 17C has a structure where the other of the source and the drain of the transistor Tp7 is connected to the node N2 and the one of the source and the drain of the transistor Tp6 is connected to the wiring 106 in the structure of the unit circuit 100A. With this structure, the transistor Tp6 can be connected to the node N2 through the transistor Tp7; thus, the influence of noise of the clock signal CK1 supplied to the gate of the transistor Tp6 on the node N2 can be reduced.

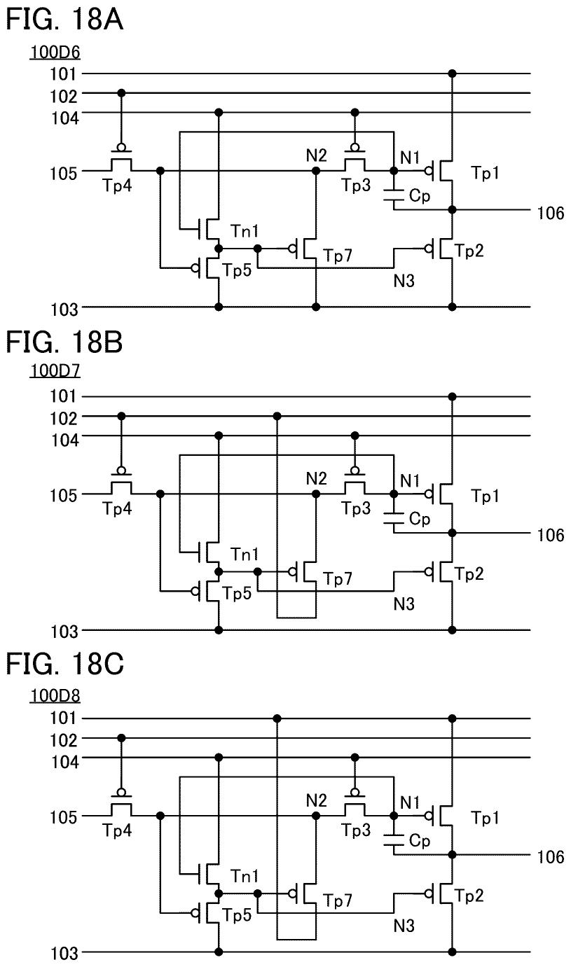

A unit circuit 100D6 illustrated in FIG. 18A has a structure where the transistor Tp6 is omitted in the structure of the unit circuit 100A. With this structure, the number of transistors included in the unit circuit can be reduced. Furthermore, the influence of noise of the clock signal CK1 supplied to the gate of the transistor Tp6 on the node N2 can be reduced.

A unit circuit 100D7 illustrated in FIG. 18B has a structure where the transistor Tp6 is omitted and the other of the source and the drain of the transistor Tp7 is connected to the wiring 102 in the structure of the unit circuit 100A. This structure corresponds to a structure where the modification examples illustrated in the unit circuit 100D1 and the unit circuit 100D6 are combined. In this manner, one embodiment of the present invention can have a structure where the above-described modification examples are combined. With this structure, the load on the power supply line 103 can be reduced as well as reducing the number of transistors included in the unit circuit.

A unit circuit 100D8 illustrated in FIG. 18C has a structure where the transistor Tp6 is omitted and the other of the source and the drain of the transistor Tp7 is connected to the wiring 101 in the structure of the unit circuit 100A. With this structure, the load on the power supply line 103 can be reduced as well as reducing the number of transistors included in the unit circuit.

Modification examples shown in the unit circuits 100D1 to 100D8 can be combined with the above-described modification examples of the unit circuits 100B1 to 100B8 and the unit circuits 100C1 to 100C3. With this structure, the load on the power supply line 103 can be reduced, the parasitic capacitance of the node N2 can be reduced, and/or the number of transistors can be reduced.

### Modification Example 4 of Unit Circuit 100A

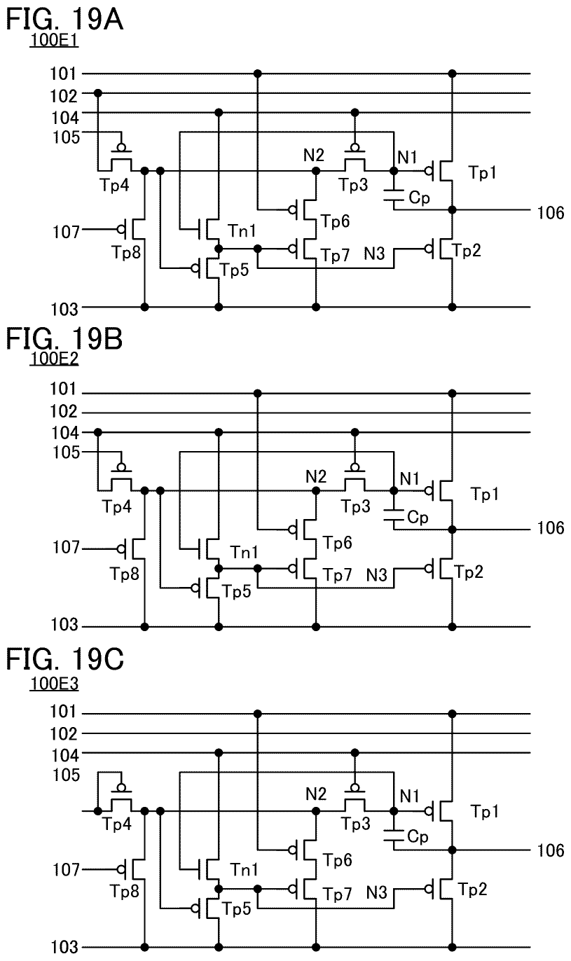

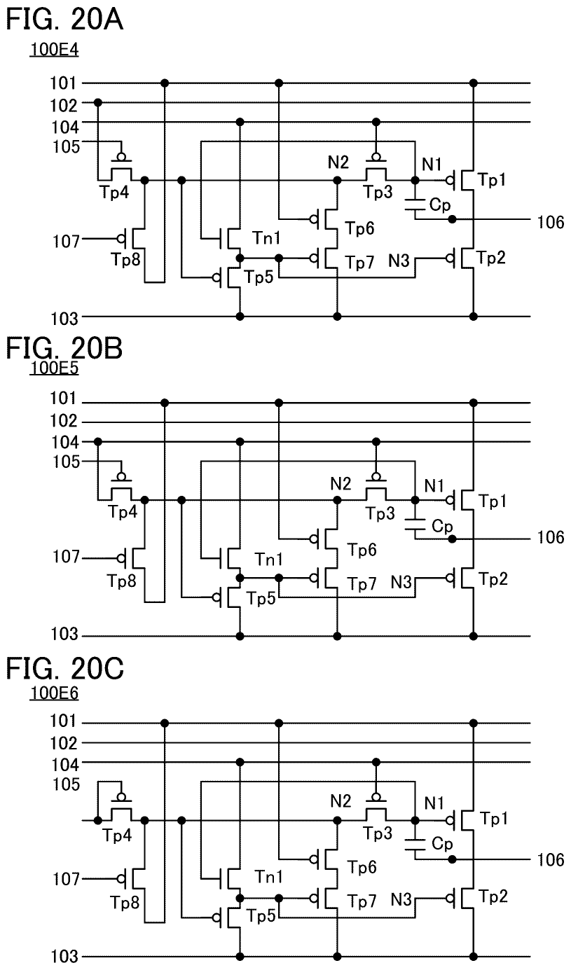

In the unit circuit 100A, wirings or transistors to which the transistor Tp4 is connected can have structures in FIGS. 19A to 20C. Unit circuits 100E1 to 100E6 illustrated in FIGS. 19A to 20C each have a structure in which a transistor Tp8 is added. The transistor Tp8 is a p-channel transistor like the transistors Tp1 to Tp7.

A unit circuit 100E1 illustrated in FIG. 19A has a structure where the gate of the transistor Tp4 is connected to the wiring 105 and the other of the source and the drain of the transistor Tp4 is connected to the wiring 102 in the structure of the unit circuit 100A. The unit circuit 100E1 has a structure where a gate of the transistor Tp8 is connected to a wiring 107, one of a source and a drain is connected to the node N2, and the other of the source and the drain is connected to the power supply line 103. With this structure, the H level can be periodically supplied to N1 and N2 regardless of the state of the transistor Tp4, which enables the continuous off state of the transistor Tp1 that is a pull-up transistor.

The wiring 107 has a function of a reset line to which a reset signal is supplied. The reset signal is a signal for supplying an H-level potential to the node N2 periodically.

A unit circuit 100E2 illustrated in FIG. 19B has a structure where the gate of the transistor Tp4 is connected to the wiring 105 and the other of the source and the drain of the transistor Tp4 is connected to the power supply line 104 in the structure of the unit circuit 100A. The unit circuit 100E2 has a structure where the gate of the transistor Tp8 is connected to the wiring 107, one of the source and the drain is connected to the node N2, and the other of the source and the drain is connected to the power supply line 103. With this structure, the H level can be periodically supplied to N1 and N2 regardless of the state of the transistor Tp4, which enables the continuous off state of the transistor Tp1 that is a pull-up transistor.

A unit circuit 100E3 illustrated in FIG. 19C has a structure where the gate of the transistor Tp4 and the other of the source and the drain of the transistor Tp4 are connected to the wiring 105 in the structure of the unit circuit 100A. The unit circuit 100E3 has a structure where the gate of the transistor Tp8 is connected to the wiring 107, one of the source and the drain is connected to the node N2, and the other of the source and the drain is connected to the power supply line 103. With this structure, the H level can be periodically supplied to N1 and N2 regardless of the state of the transistor Tp4, which enables the continuous off state of the transistor Tp1 that is a pull-up transistor. Alternatively, the wiring 102 can be omitted.

A unit circuit 100E4 illustrated in FIG. 20A has a structure where the gate of the transistor Tp4 is connected to the wiring 105 and the other of the source and the drain of the transistor Tp4 is connected to the wiring 102 in the structure of the unit circuit 100A. The unit circuit 100E4 has a structure where the gate of the transistor Tp8 is connected to the wiring 107, one of the source and the drain is connected to the node N2, and the other of the source and the drain is connected to the wiring 101. With this structure, the H level can be periodically supplied to N1 and N2 regardless of the state of the transistor Tp4, which enables the continuous off state of the transistor Tp1 that is a pull-up transistor. In addition, even though the transistor Tp8 is added, the number of transistors connected to the power supply line 103 does not increase, so that an increase in the load on the power supply line 103 can be inhibited.

A unit circuit 100E5 illustrated in FIG. 20B has a structure where the gate of the transistor Tp4 is connected to the wiring 105 and the other of the source and the drain of the transistor Tp4 is connected to the power supply line 104 in the structure of the unit circuit 100A. The unit circuit 100E5 has a structure where the gate of the transistor Tp8 is connected to the wiring 107, one of the source and the drain is connected to the node N2, and the other of the source and the drain is connected to the wiring 101. With this structure, the H level can be periodically supplied to N1 and N2 regardless of the state of the transistor Tp4, which enables the continuous off state of the transistor Tp1 that is a pull-up transistor. In addition, even though the transistor Tp8 is added, the number of transistors connected to the power supply line 103 does not increase, so that an increase in the load on the power supply line 103 can be inhibited. Alternatively, the wiring 102 can be omitted.

A unit circuit 100E6 illustrated in FIG. 20C has a structure where the gate of the transistor Tp4 and the other of the source and the drain of the transistor Tp4 are connected to the wiring 105 in the structure of the unit circuit 100A. The unit circuit 100E6 has a structure where the gate of the transistor Tp8 is connected to the wiring 107, one of the source and the drain is connected to the node N2, and the other of the source and the drain is connected to the wiring 101. With this structure, the H level can be periodically supplied to N1 and N2 regardless of the state of the transistor Tp4, which enables the continuous off state of the transistor Tp1 that is a pull-up transistor. In addition, even though the transistor Tp8 is added, the number of transistors connected to the power supply line 103 does not increase, so that an increase in the load on the power supply line 103 can be inhibited. Alternatively, the wiring 102 can be omitted.

The modification examples shown in the unit circuits 100E1 to 100E6 can be combined with the above-described modification examples of the unit circuits 100B1 to 100B8, the unit circuits 100C1 to 100C3, and the unit circuits 100D1 to 100D8. With this structure, the load on the power supply line 103 can be reduced, the parasitic capacitance of the node N2 can be reduced, and/or the number of transistors can be reduced.

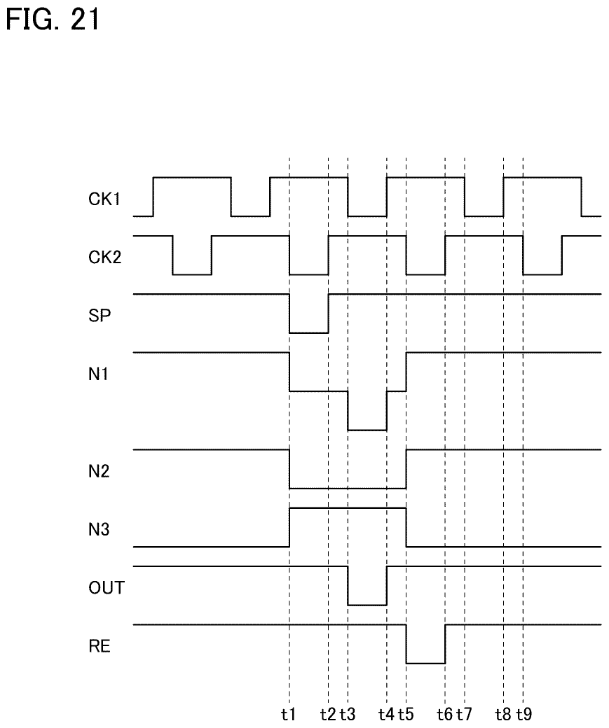

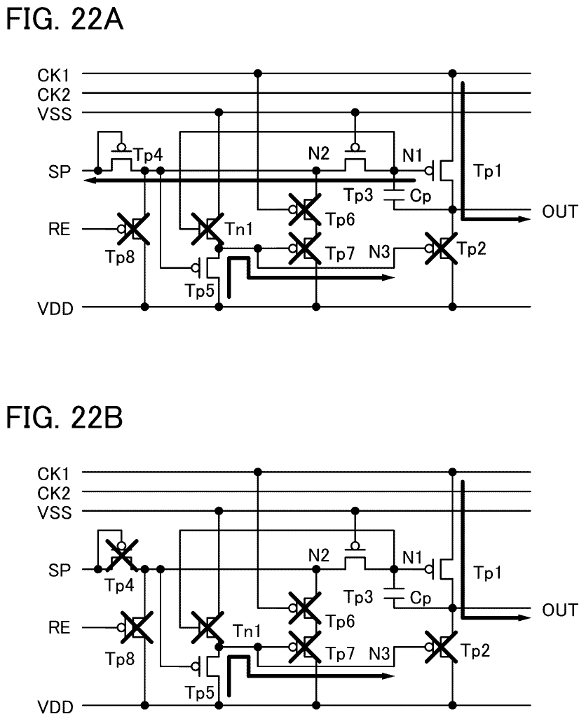

To illustrate an operation example of the circuit diagrams illustrated in FIGS. 19A to 20C, FIG. 21 illustrates a timing chart of the unit circuit 100E3 illustrated in FIG. 19C. FIGS. 22A to 25B are circuit diagrams schematically illustrating operation from time t1 to time t9 shown in FIG. 21. Note that in the description of FIG. 21 and FIGS. 22A to 25B, the above descriptions in FIG. 7B and FIGS. 8A to 11B are referred to for the same structure, and the description thereof is omitted in some cases.

RE shown in FIG. 21 is a reset signal supplied to the wiring 107. In addition, CK1, CK2, SP, N1, N2, N3, and OUT are similar to those in the description of FIG. 7B.

FIG. 22A is a diagram illustrating operation in the period between time t1 and time t2 illustrated in FIG. 21. The transistors Tp1 and Tp3 to Tp5 are turned on, and the transistors Tp2, Tp6, Tp7, Tp8, and Tn1 are turned off by CK1, CK2, SP, RE, VDD, and VSS. OUT becomes an H-level potential of CK1. N1 and N2 become the L level of SP. N3 becomes VDD, that is, the H level.

FIG. 22B is a diagram illustrating operation in the period between time t2 and time t3 illustrated in FIG. 21. The transistors Tp1, Tp3, and Tp5 are turned on, and the transistors Tp2, Tp4, Tp6, Tp7, Tp8, and Tn1 are turned off by CK1, CK2, SP, RE, VDD, and VSS. OUT becomes an H-level potential of CK1. Since the transistors Tp4, Tp6, Tp7, and Tp8 are turned off, N1 and N2 are brought into a floating state. Thus, the L level of SP is retained in N1 and N2. N3 remains at VDD, i.e., the H level.

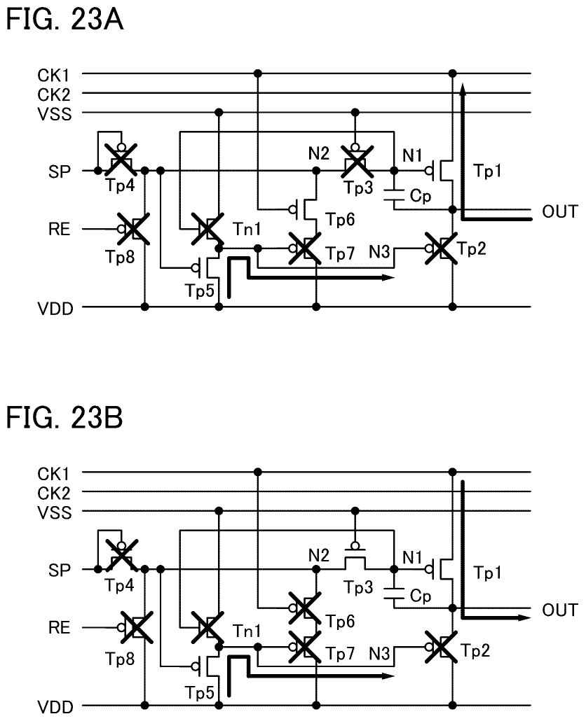

FIG. 23A is a diagram illustrating operation in the period between time t3 and time t4 illustrated in FIG. 21. The transistors Tp1, Tp5, and Tp6 are turned on, and the transistors Tp2 to Tp4, Tp7, Tp8, and Tn1 are turned off by CK1, CK2, SP, RE, VDD, and VSS.

In the period between time t3 and time t4, since the transistors Tp4, Tp7, and Tp8 are turned off, N1 and N2 are floating. Since the potential difference between the electrodes at both ends of the capacitor Cp is maintained, the potential of N1 changes along with the change in OUT. Specifically, as CK1 changes from the H level to the L level, the potential of N1 also decreases. As the potential of N1 decreases, the gate-source voltage (Vgs) of the transistor Tp3 becomes higher than or equal to the threshold voltage (Vth<0), so that the transistor Tp3 is turned off. N2 becomes VSS−Vth, which is a potential lower than VSS by the threshold voltage (Vth) of the transistor Tp3, and N1 becomes a potential lower than VSS−Vth. The potentials of the signals with the same logic level, e.g., the L-level in N1 and N2 can be made different with the transistor Tp3, which is a potential adjustment transistor.

When N1 becomes a potential lower than VSS−Vth, OUT can be decreased to VSS. N3 remains at VDD, i.e., the H level.

In one embodiment of the present invention, in order to control the on state of the transistor Tn1 and the off state of the transistor Tp5 that operate at the same logic level (L level) with different potentials, the gate of the transistor Tn1 is connected to the node N1 and the gate of the transistor Tp5 is connected to the node N2.

The potential of the node N1 is lower than the potential of the node N2. The potential of the node N1 is set to an off-level signal of the transistor Tn1 which is an n-channel transistor, so that the transistor Tn1 can be turned off more reliably. The potential of the node N1 is lower than VSS and thus deterioration and dielectric breakdown of the transistor might be induced; however, the deterioration and dielectric breakdown of the transistor can be prevented owing to the transistor Tn1 that is an OS transistor.

VSS−Vth of the node N2 is higher than the potential of the node N1. The potential of the node N2 is set to an on-level signal of the transistor Tp5 which is a p-channel transistor, so that the transistor can be turned on without deterioration and dielectric breakdown thereof. Since the potential of the node N2 is lower than the potential of the node N1, deterioration and/or dielectric breakdown of the transistors Tp3, Tp4, and Tp8 which are other transistors connected to the node N2 can be prevented.

FIG. 23B is a diagram illustrating operation in the period between time t4 and time t5 illustrated in FIG. 21. The transistors Tp1, Tp3, and Tp5 are turned on, and the transistors Tp2, Tp4, Tp6, Tp7, Tp8, and Tn1 are turned off by CK1, CK2, SP, RE, VDD, and VSS. OUT becomes an H-level potential of CK1. Since the transistors Tp4, Tp6, Tp7, and Tp8 are turned off, N1 and N2 are brought into a floating state. Thus, the L level of SP is retained in N1 and N2. N3 remains at VDD, i.e., the H level.

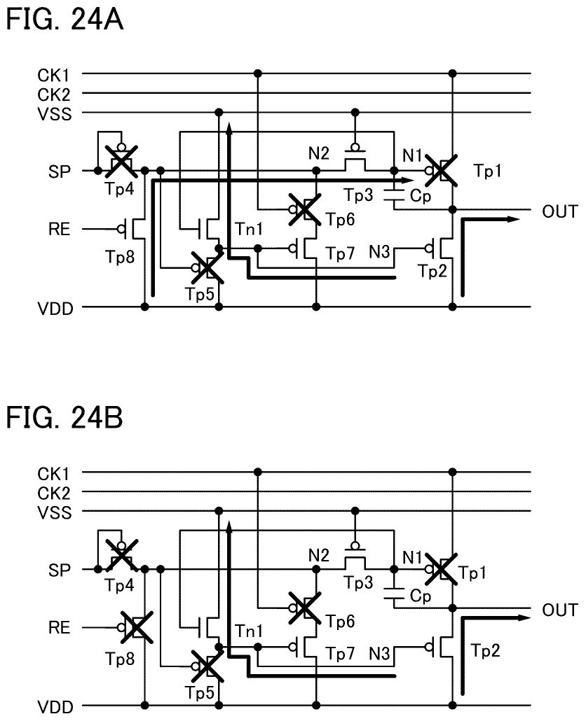

FIG. 24A is a diagram illustrating operation in the period between time t5 and time t6 illustrated in FIG. 21. The transistors Tp2, Tp3, Tp7, and Tp8 and the transistor Tn1 are turned on, and the transistors Tp1, Tp4, Tp5, and Tp6 are turned off by CK1, CK2, SP, RE, VDD, and VSS. OUT becomes VDD. Since the transistor Tp8 is turned on, N1 and N2 become the H level. With this structure, the H level is periodically supplied to N1 and N2, which enables the continuous off state of the transistor Tp1 that is a pull-up transistor. N3 becomes VSS, that is, the L level.

FIG. 24B is a diagram illustrating operation in the period between time t6 and time t7 illustrated in FIG. 21. The transistors Tp2, Tp3, Tp7, and Tn1 are turned on, and the transistors Tp1, Tp4, Tp5, Tp6, and Tp8 are turned off by CK1, CK2, SP, RE, VDD, and VSS. OUT remains at VDD. Since the transistors Tp4, Tp6, and Tp8 are turned off, N1 and N2 are brought into a floating state. Thus, VDD, i.e., the H level, is retained in N1 and N2. N3 remains at VSS, i.e., the L level.

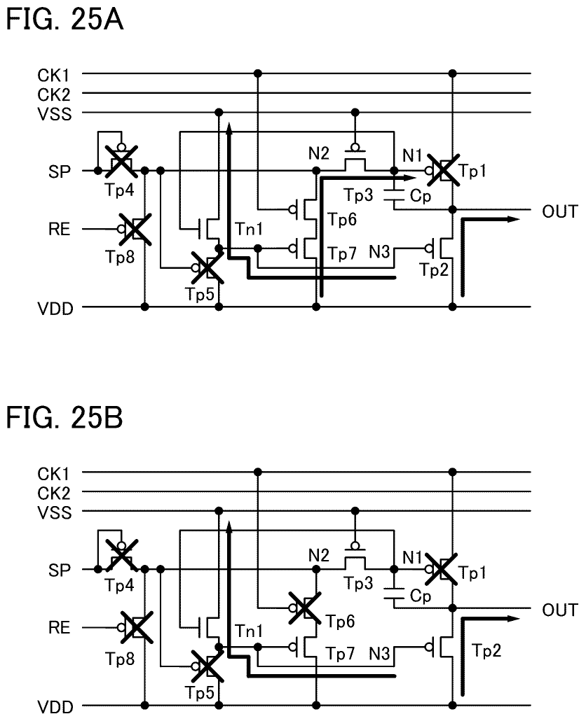

FIG. 25A is a diagram illustrating operation in the period between time t7 and time t8 illustrated in FIG. 21. The transistors Tp2, Tp3, Tp6, and Tp7 and the transistor Tn1 are turned on and the transistors Tp1, Tp4, Tp5, and Tp8 are turned off by CK1, CK2, SP, RE, VDD, and VSS. OUT remains at VDD. Since the transistors Tp6 and Tp7 are turned on, N1 and N2 become the H level. With this structure, the H level is periodically supplied to N1 and N2, which enables the continuous off state of the transistor Tp1 that is a pull-up transistor. N3 remains at VSS, i.e., the L level.

FIG. 25B is a diagram illustrating operation in the period between time t8 and time t9 illustrated in FIG. 21. The transistors Tp2, Tp3, Tp7, and Tn1 are turned on, and the transistors Tp1, Tp4, Tp5, Tp6, and Tp8 are turned off by CK1, CK2, SP, RE, VDD, and VSS. OUT remains at the potential of VDD at the power supply line 103. Since the transistors Tp4, Tp6, and Tp8 are turned off, N1 and N2 are brought into a floating state. Thus, VDD, i.e., the H level, is retained in N1 and N2. N3 remains at VSS, i.e., the L level.

### Modification Example 5 of Unit Circuit 100A

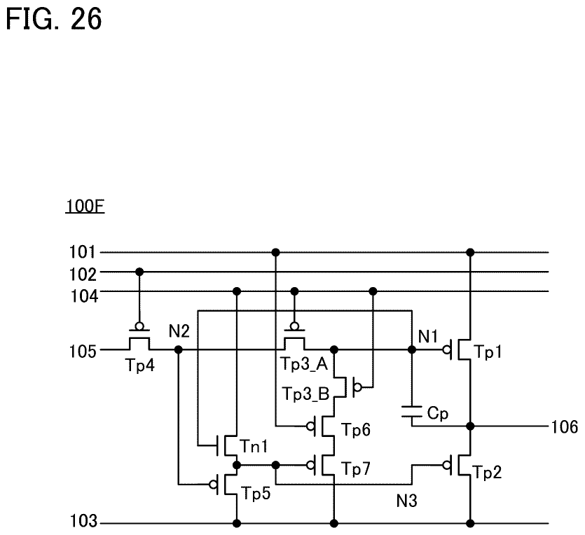

In the unit circuit 100A, the node N1 to which the transistor Tp3 is connected can have a structure in FIG. 26. In a unit circuit 100F illustrated in FIG. 26, transistors Tp3_A and Tp3_B are provided as transistors functioning as the transistor Tp3. The transistors Tp3_A and Tp3_B are p-channel transistors like the transistors Tp1 to Tp7.

With the structure in FIG. 26, a transistor for potential adjustment can be provided between the node N1 and the transistor Tp6. The potential of the node N1 becomes lower than VSS and thus deterioration and dielectric breakdown of the transistor might be induced; however, providing the transistor Tp3_B makes the potential of a node between the transistor Tp6 and the transistor Tp3_B substantially equal to the potential of the node N2. As a result, deterioration and/or dielectric breakdown of the transistor Tp6 can be prevented.

VSS−Vth of the node N2 can be higher than the potential of the node N1 by providing the transistor Tp3_A. The potential of the node N2 is set to an on-level signal of the transistor Tp5 which is a p-channel transistor, so that the transistor can be turned on without deterioration and dielectric breakdown thereof. The potential of the node N2 is lower than that of the node N1, and deterioration and/or dielectric breakdown of the transistors Tp4 and Tp5, which are other transistors connected to the node N2, can be prevented.

The modification examples shown in the unit circuit 100F can be combined with the above-described modification examples of the unit circuits 100B1 to 100B8, the unit circuits 100C1 to 100C3, the unit circuits 100D1 to 100D8, and the unit circuits 100E1 to 100E6. With this structure, the load on the power supply line 103 can be reduced, the parasitic capacitance of the node N2 can be reduced, and/or the number of transistors can be reduced.

### Modification Example 6 of Unit Circuit 100A

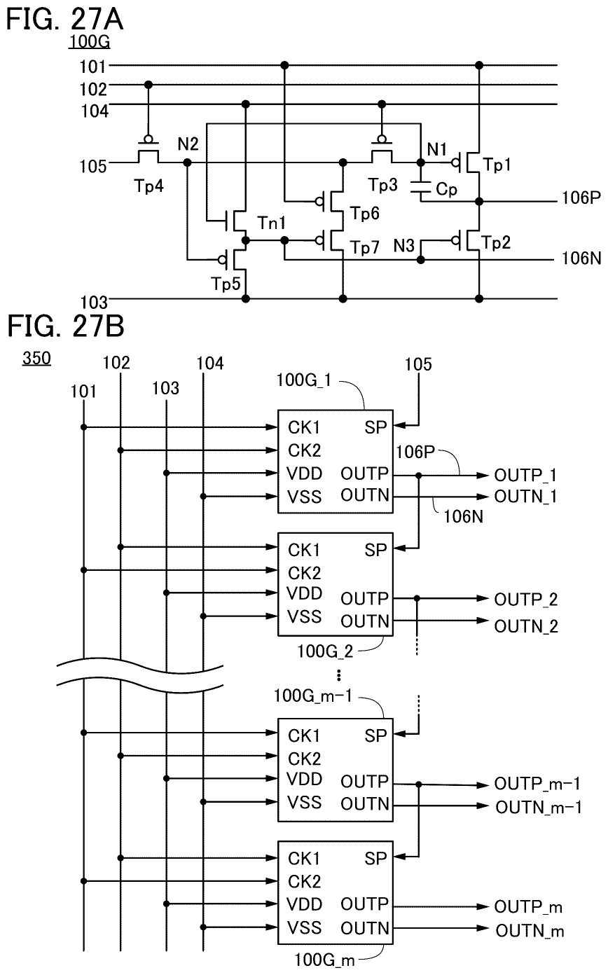

In the unit circuit 100A, the output signal OUT can be two or more. A unit circuit 100G illustrated in FIG. 27A includes wirings 106P and 106N that output output signals. The wiring 106P outputs an output signal OUTP corresponding to the output signal OUT outputted from the above unit circuit 100A. The wiring 106N outputs an output signal OUTN in accordance with a change in the potential of the node N3. FIG. 27B is a circuit diagram of the shift register 350 including the unit circuit 100G illustrated in FIG. 27A. The unit circuit 100G illustrated in FIG. 27A can be used as unit circuits 100G_1 to 100G_m provided in each row.

As illustrated in FIG. 27B, the output signal OUTP is suitable as a selection signal for turning on a p-channel transistor. The output signal OUTN is suitable as a selection signal for turning on an n-channel transistor. Thus, the structure of the unit circuit 100G can be suitably used for a pixel circuit having a structure of LTPO.

The modification examples shown in the unit circuit 100G can be combined with the above-described modification examples of the unit circuits 100B1 to 100B8, the unit circuits 100C1 to 100C3, the unit circuits 100D1 to 100D8, the unit circuits 100E1 to 100E6, and the unit circuit 100F. With this structure, the load on the power supply line 103 can be reduced, the parasitic capacitance of the node N2 can be reduced, and/or the number of transistors can be reduced.

Note that the gate of the transistor Tn1 may be connected to the node N2 in the unit circuit 100, the unit circuit 100A, the unit circuits 100B1 to 100B8, the unit circuits 100C1 to 100C3, the unit circuits 100D1 to 100D8, the unit circuits 100E1 to 100E6, the unit circuit 100F, the unit circuit 100G, and a unit circuit where these circuits are combined. When the gate of the transistor Tn1 is connected to the node N2, deterioration and/or dielectric breakdown of the transistor Tn1 can be prevented. Thus, an LTPS transistor can be easily used as the transistor Tn1. Needless to say, even in the case where the gate of the transistor Tn1 is connected to the node N2, an OS transistor can also be used as the transistor Tn1.

Note that in the unit circuits described in this embodiment, a load driven by the transistor Tp1 is larger than loads driven by the transistors Tp3, Tp4, Tp5, Tp6, Tp7, and Tp8. Thus, W (channel width)/L (channel length) of the transistor Tp1 is preferably higher than W/L of the transistor Tp3. The W/L of the transistor Tp1 is preferably higher than that of the transistor Tp4. The W/L of the transistor Tp1 is preferably higher than that of the transistor Tp5. The W/L of the transistor Tp1 is preferably higher than that of the transistor Tp6. The W/L of the transistor Tp1 is preferably higher than that of the transistor Tp7. The W/L of the transistor Tp1 is preferably higher than that of the transistor Tp8. The load driven by the transistor Tp1 is larger than the sum of the loads driven by the transistors Tp3, Tp4, Tp5, Tp6, Tp7, and Tp8. Therefore, the W/L of the transistor Tp1 is preferably higher than the sum of the W/L of the transistors Tp3, Tp4, Tp5, Tp6, Tp7, and Tp8. It is needless to say that the W/L of the transistor Tp1 is preferably higher than the sum of the W/L of at least two of the transistors Tp3, Tp4, Tp5, Tp6, Tp7, and Tp8. For example, it is preferable that the W/L of the transistor Tp1 be higher than the sum of the W/L of the transistors Tp3, Tp4, Tp5, Tp6, and Tp7 and be higher than the sum of the W/L of the transistors Tp3, Tp4, and Tp5.

Note that in the unit circuits described in this embodiment, a load driven by the transistor Tp2 is larger than the loads driven by the transistors Tp3, Tp4, Tp5, Tp6, Tp7, and Tp8. Thus, W (channel width)/L (channel length) of the transistor Tp2 is preferably higher than the W/L of the transistor Tp3. The W/L of the transistor Tp2 is preferably higher than that of the transistor Tp4. The W/L of the transistor Tp2 is preferably higher than that of the transistor Tp5. The W/L of the transistor Tp2 is preferably higher than that of the transistor Tp6. The W/L of the transistor Tp2 is preferably higher than that of the transistor Tp7. The W/L of the transistor Tp2 is preferably higher than that of the transistor Tp8. The load driven by the transistor Tp2 is larger than the sum of the loads driven by the transistors Tp3, Tp4, Tp5, Tp6, Tp7, and Tp8. Therefore, the W/L of the transistor Tp2 is preferably higher than the sum of the W/L of the transistors Tp3, Tp4, Tp5, Tp6, Tp7, and Tp8. It is needless to say that the W/L of the transistor Tp2 is preferably higher than the sum of the W/L of at least two of the transistors Tp3, Tp4, Tp5, Tp6, Tp7, and Tp8. For example, it is preferable that the W/L of the transistor Tp2 be higher than the sum of the W/L of the transistors Tp3, Tp4, Tp5, Tp6, and Tp7 and be higher than the sum of the W/L of the transistors Tp3, Tp4, and Tp5.

Note that in the unit circuits described in this embodiment, while the transistor Tp1 changes the potential of OUT, the transistor Tp2 maintains the potential of OUT. The load of the transistor Tp1 is extremely large. Therefore, the W/L of the transistor Tp1 is preferably higher than that of the transistor Tp2. The load driven by the transistor Tp1 is higher the sum of the loads driven by the transistors Tp2, Tp3, Tp4, Tp5, Tp6, Tp7, and Tp8. Therefore, the W/L of the transistor Tp1 is preferably higher than the sum of W/L of the transistors Tp2, Tp3, Tp4, Tp5, Tp6, Tp7, and Tp8. It is needless to say that the W/L of the transistor Tp1 is preferably higher than the sum of the W/L of at least two of the transistors Tp2, Tp3, Tp4, Tp5, Tp6, Tp7, and Tp8.

Note that in the unit circuits described in this embodiment, when an OS transistor is used as the transistor Tn1 and LTPS transistors are used as the transistors Tp1, Tp2, Tp3, Tp4, Tp5, Tp6, Tp7, and Tp8, the mobility of the transistor Tn1 is lower than that of the transistors Tp1, Tp2, Tp3, Tp4, Tp5, Tp6, Tp7, and Tp8. Therefore, the W/L of the transistor Tn1 is preferably higher than that of the transistor Tp1. The W/L of the transistor Tn1 is preferably higher than that of the transistor Tp2. The W/L of the transistor Tn1 is preferably higher than that of the transistor Tp3. The W/L of the transistor Tn1 is preferably higher than that of the transistor Tp4. The W/L of the transistor Tn1 is preferably higher than that of the transistor Tp5. The W/L of the transistor Tn1 is preferably higher than that of the transistor Tp6. The W/L of the transistor Tn1 is preferably higher than that of the transistor Tp7. The W/L of the transistor Tn1 is preferably higher than that of the transistor Tp8. Note that since the transistor Tp1 is charged and discharged with a large load, the W/L of the transistor Tp1 may be higher than that of the transistor Tn1.

A signal from the SP is transmitted to the gate of the transistor Tp1 through the transistors Tp4 and Tp3. Therefore, increasing the drive capability of the transistors Tp4 and Tp3 can improve the operating speed. Therefore, the W/L of the transistor Tp3 is preferably higher than that of the transistor Tp5. The W/L of the transistor Tp3 is preferably higher than that of the transistor Tp6. The W/L of the transistor Tp3 is preferably higher than that of the transistor Tp7. The W/L of the transistor Tp3 is preferably higher than that of the transistor Tp8. The W/L of the transistor Tp4 is preferably higher than that of the transistor Tp5. The W/L of the transistor Tp4 is preferably higher than that of the transistor Tp6. The W/L of the transistor Tp4 is preferably higher than that of the transistor Tp7. The W/L of the transistor Tp4 is preferably higher than that of the transistor Tp8.

This embodiment can be combined with any of the other embodiments as appropriate.

### Embodiment 2

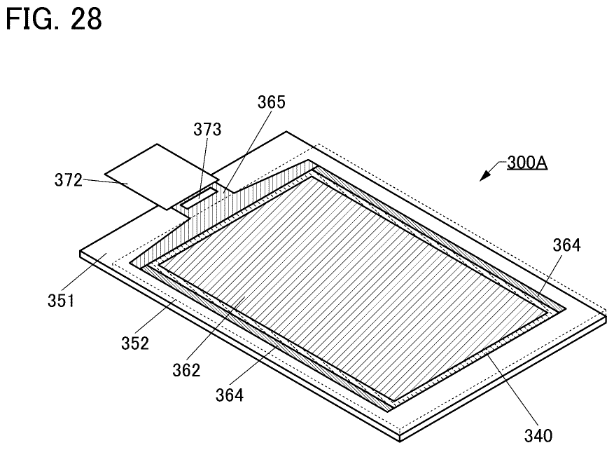

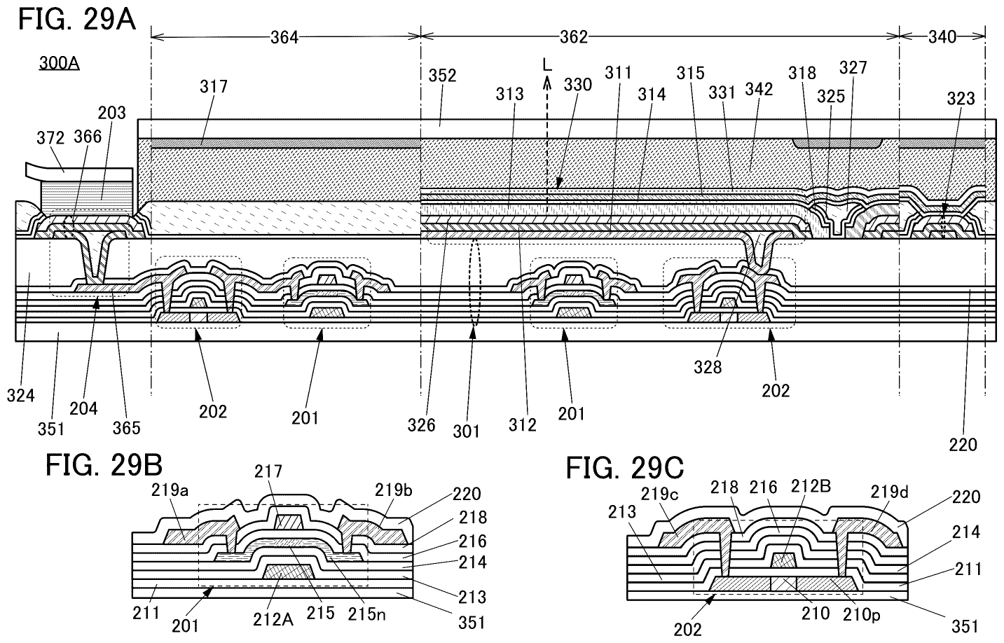

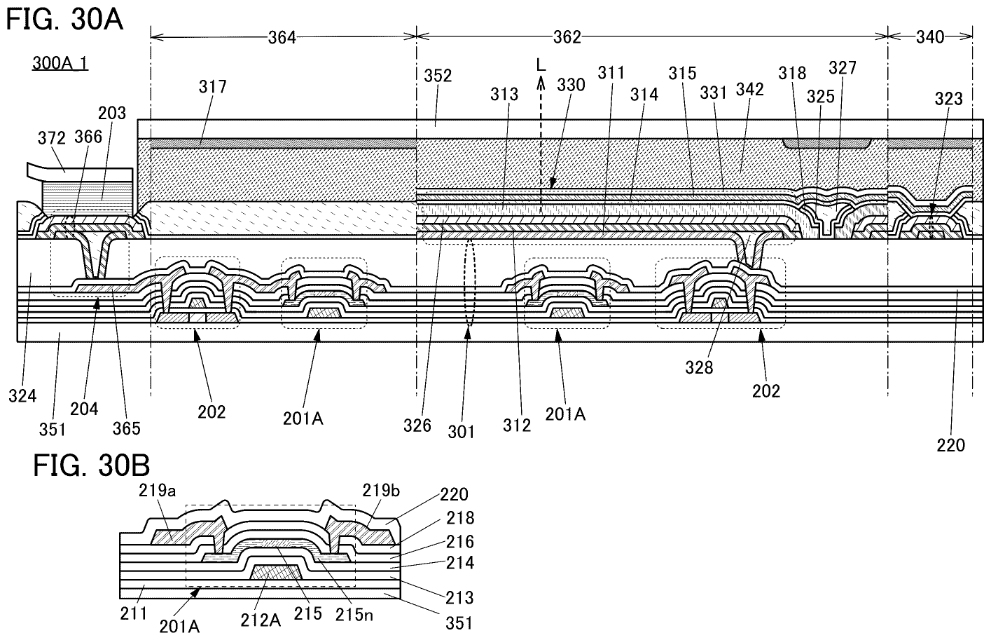

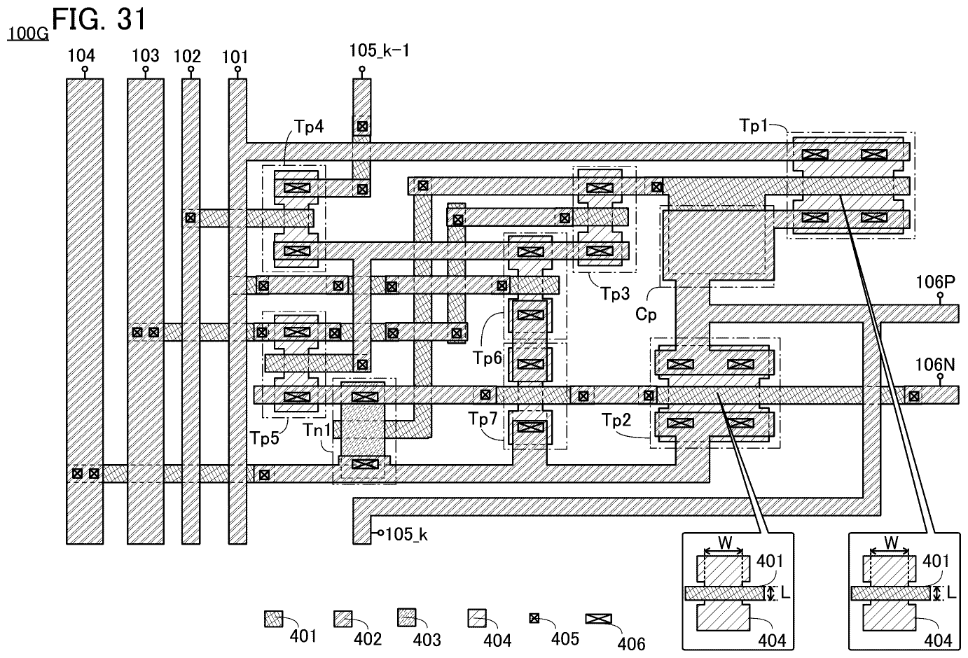

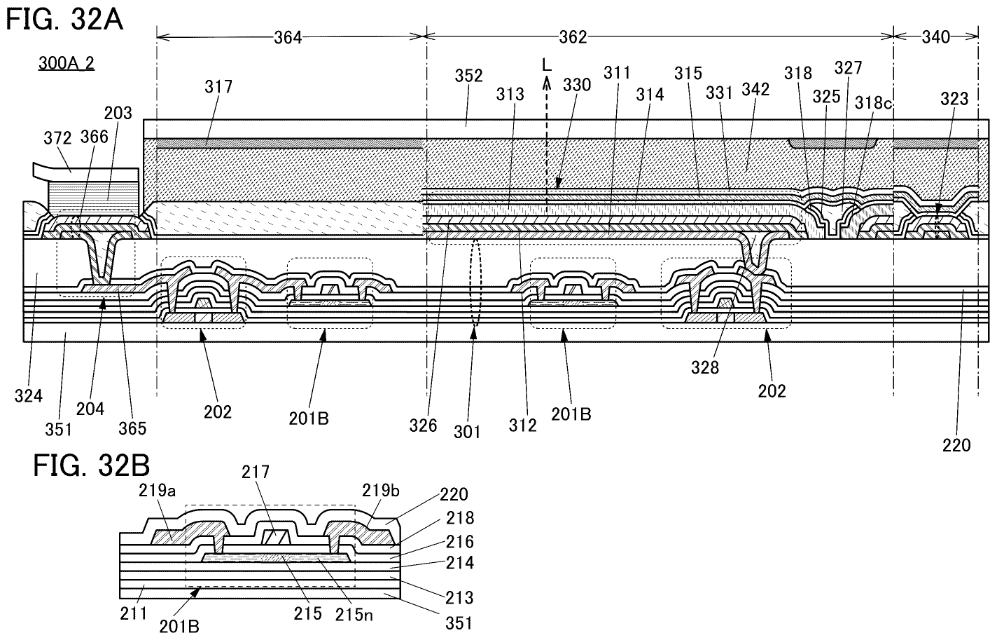

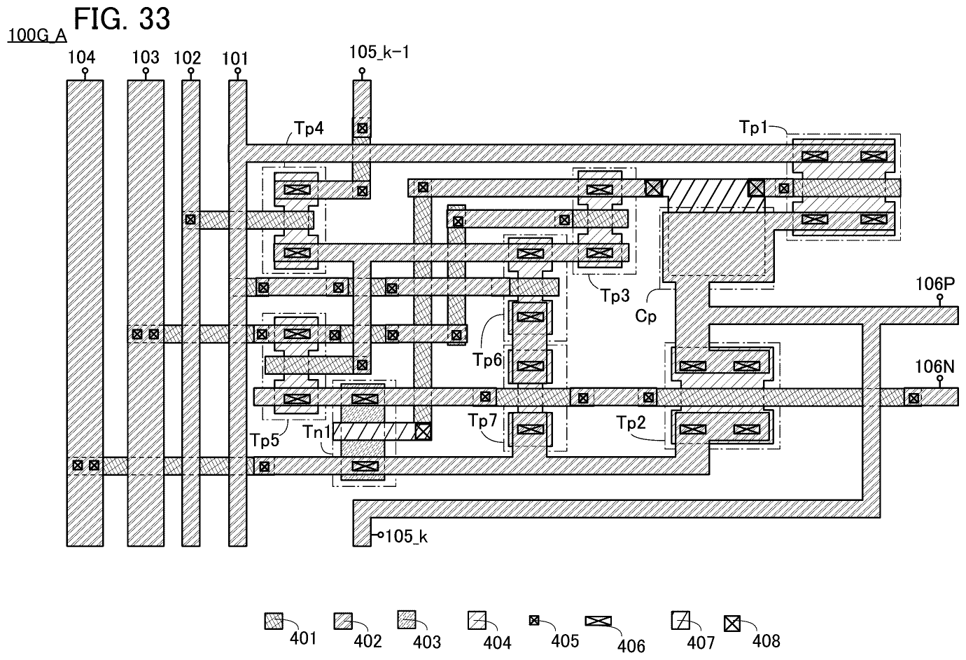

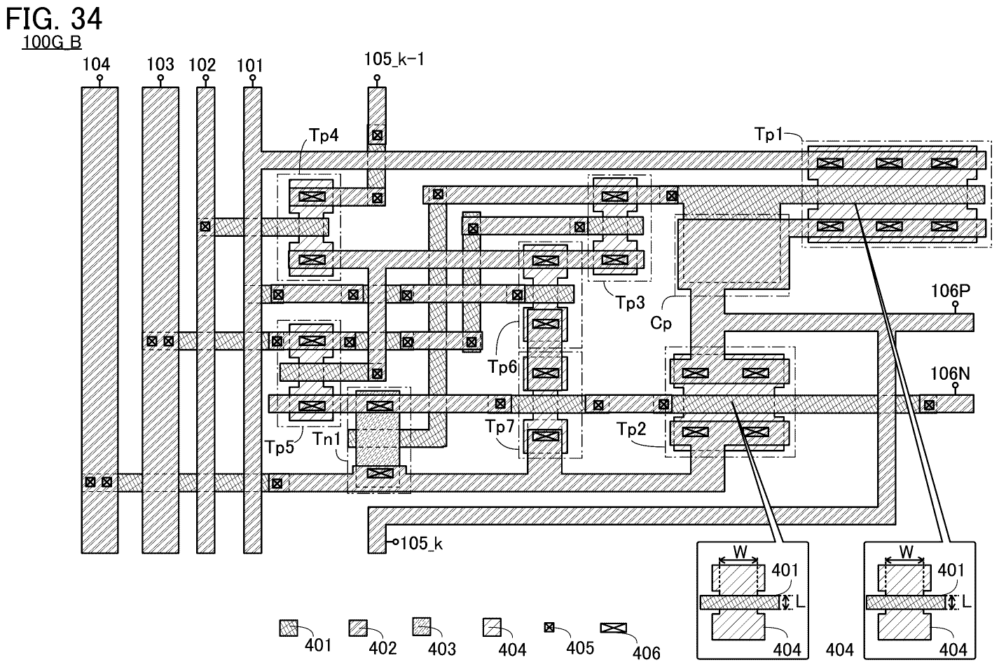

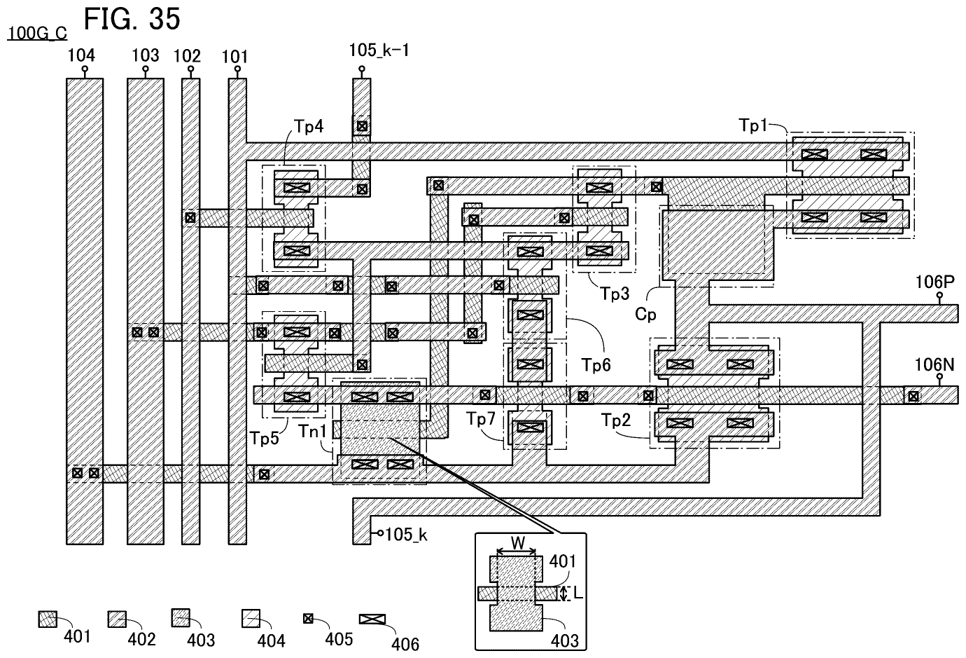

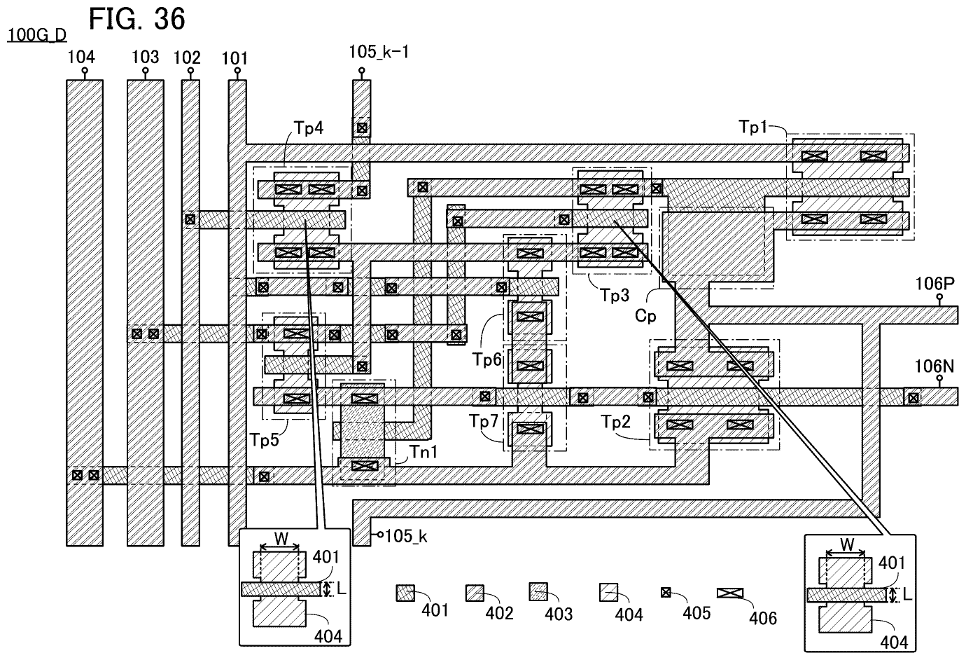

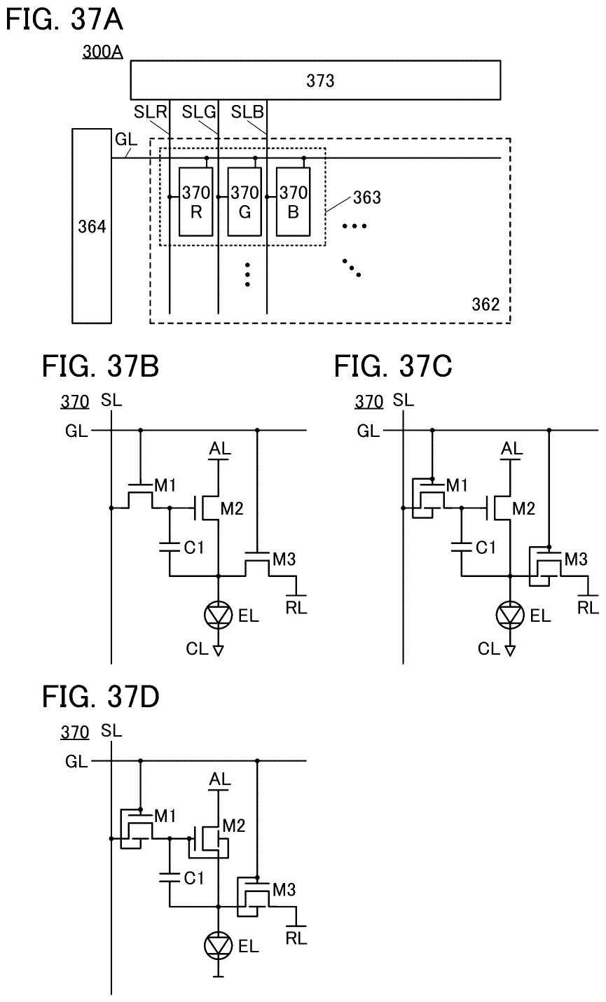

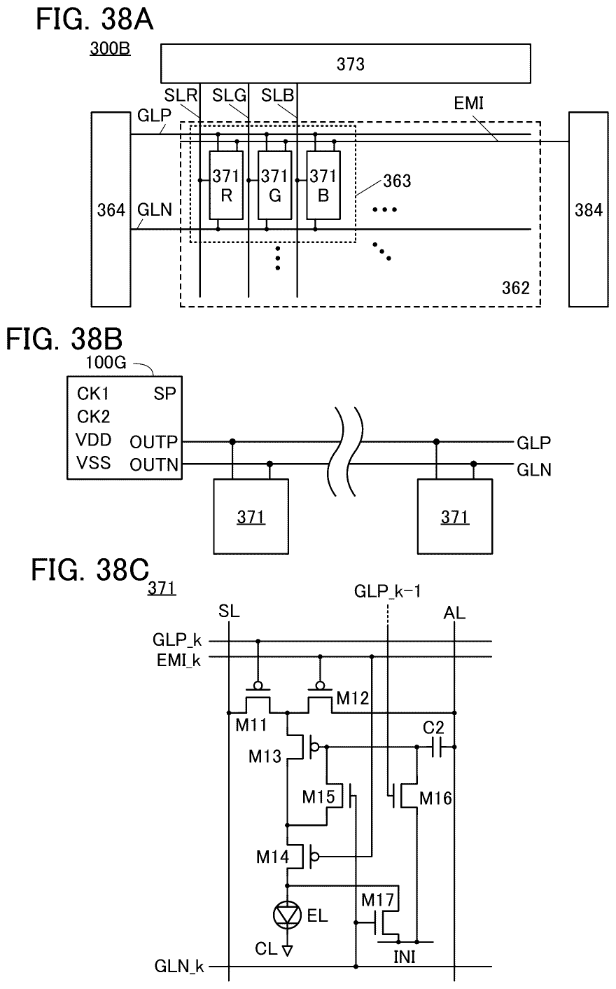

In this embodiment, display apparatuses of one embodiment of the present invention are described with reference to FIG. 28, FIG. 29, FIG. 30, FIG. 31, FIG. 32, FIG. 33, FIG. 34, FIG. 35, FIG. 36, FIGS. 37A to 37D, and FIGS. 38A to 38C.

### <Perspective View and Cross-Sectional View of Display Apparatus>

FIG. 28 is a perspective view of a display apparatus 300A, and FIG. 29A is a cross-sectional view of the display apparatus 300A. FIGS. 29B and 29C are diagrams illustrating structure examples of transistors in the cross-sectional view of FIG. 29A.

In the display apparatus 300A, a substrate 352 and a substrate 351 are bonded to each other. In FIG. 28, the substrate 352 is denoted by a dashed line.

The display apparatus 300A includes the display portion 362, a connection portion 340, the gate line driver circuit 364, a wiring 365, and the like. FIG. 28 illustrates an example in which an IC 373 and an FPC 372 are mounted on the display apparatus 300A. Thus, the structure illustrated in FIG. 28 can be regarded as a display module including the display apparatus 300A, the IC (integrated circuit), and the FPC.

The connection portion 340 is provided outside the display portion 362. The connection portion 340 can be provided along one or more sides of the display portion 362. The number of connection portions 340 may be one or more. FIG. 28 illustrates an example in which the connection portion 340 is provided to surround the four sides of the display portion. A common electrode of a light-emitting device is connected to a conductive layer in the connection portion 340, and thus a potential can be supplied to the common electrode.

As the gate line driver circuit 364, the gate line driver circuit 364 including the unit circuit 100, the unit circuit 100A, or the like described in Embodiment 1 can be used, for example.

The wiring 365 has a function of supplying a signal and power to the display portion 362 and the gate line driver circuit 364. The signal and power are input to the wiring 365 from the outside through the FPC 372 or from the IC 373.

FIG. 28 illustrates an example in which the IC 373 is provided over the substrate 351 by a chip on glass (COG) method, a chip on film (COF) method, or the like. An IC including a signal line driver circuit or the like can be used as the IC 373, for example. Note that the display apparatus 300A and the display module are not necessarily provided with an IC. The IC may be mounted on the FPC by a COF method or the like.

FIG. 29A illustrates an example of cross sections of part of a region including the FPC 372, part of the gate line driver circuit 364, part of the display portion 362, part of the connection portion 340, and part of a region including an end portion of the display apparatus 300A.

The display apparatus 300A illustrated in FIG. 29A includes a light-emitting device 330 and the like in addition to a layer 301 including a transistor 201 and a transistor 202 between the substrate 351 and the substrate 352.

The light-emitting device 330 includes a conductive layer 311, a conductive layer 312 over the conductive layer 311, and a conductive layer 326 over the conductive layer 312. All of the conductive layers 311, 312, and 326 can be referred to as pixel electrodes, or one or two of them can be referred to as pixel electrodes. As the light-emitting device 330, a self-luminous light-emitting device such as an LED (Light Emitting Diode), an organic EL (Electro Luminescence) element (also referred to as an OLED (Organic LED)), an inorganic EL element, or a semiconductor laser can be used, for example. Examples of the LED include a mini LED and a micro LED. The case where an organic EL element is used for the light-emitting device 330 will be described below.

The conductive layer 311 is connected to the transistor 202 provided in the display portion 362 through an opening provided in an insulating layer 324. For example, a conductive layer functioning as a reflective electrode can be used as each of the conductive layer 311 and the conductive layer 312. For example, a conductive layer functioning as a transparent electrode can be used as the conductive layer 326.

The conductive layer 311 has a depression portion covering the opening provided in the insulating layer 324. A layer 328 is embedded in the depression portion. The layer 328 has a function of filling the depression portion of the conductive layer 311. The conductive layer 312 is provided over the conductive layer 311 and the layer 328. Thus, a region overlapping with the depression portion of the conductive layer 311 can also be used as a light-emitting region, whereby the aperture ratio of the pixel can be increased.

The layer 328 may be an insulating layer or a conductive layer. Any of a variety of inorganic insulating materials, organic insulating materials, and conductive materials can be used for the layer 328 as appropriate. In particular, the layer 328 is preferably formed using an insulating material.

An insulating layer containing an organic material can be suitably used as the layer 328. For example, an acrylic resin, a polyimide resin, an epoxy resin, a polyamide resin, a polyimide-amide resin, a siloxane resin, a benzocyclobutene-based resin, a phenol resin, and precursors of these resins can be used for the layer 328. A photosensitive resin can also be used for the layer 328. As the photosensitive resin, a positive photosensitive material or a negative photosensitive material can be used.

Using a photosensitive resin, the layer 328 can be formed only by the light-exposure and development steps; hence, adverse effects of dry etching, wet etching, or the like on the surface of the conductive layer 311 can be reduced. When the layer 328 is formed using a negative photosensitive resin, the layer 328 can sometimes be formed using the same photomask (light-exposure mask) as the photomask used for forming the opening in the insulating layer 324.

The top surface and a side surface of the conductive layer 312 and the top surface and a side surface of the conductive layer 326 are covered with a layer 313. Accordingly, a region provided with the conductive layer 312 can be entirely used as the light-emitting region of the light-emitting device 330, whereby the aperture ratio of the pixels can be increased.

A side surface of the layer 313 is covered with an insulating layer 325 and an insulating layer 327. A sacrifice layer 318 is positioned between the layer 313 and the insulating layer 325. A layer 314 is provided over the layer 313, the insulating layer 325, and the insulating layer 327. A common electrode 315 is provided over the layer 314. The layer 314 and the common electrode 315 are each one continuous film shared by the plurality of light-emitting devices 330. A protective layer 331 is provided over the light-emitting device 330.

The protective layer 331 and the substrate 352 are bonded to each other with an adhesive layer 342. A solid sealing structure, a hollow sealing structure, or the like can be employed for sealing of the light-emitting device 330. In FIG. 29A, a solid sealing structure is employed, in which a space between the substrate 352 and the substrate 351 is filled with the adhesive layer 342. Alternatively, a hollow sealing structure may be employed, in which the space is filled with an inert gas (e.g., nitrogen or argon). In that case, the adhesive layer 342 may be provided not to overlap with the light-emitting device. Alternatively, the space may be filled with a resin other than the frame-like adhesive layer 342.

A conductive layer 323 is provided over the insulating layer 324 in the connection portion 340. An example is illustrated in which the conductive layer 323 has a stacked-layer structure of a conductive film obtained by processing the same conductive film as the conductive layer 311, a conductive film obtained by processing the same conductive film as the conductive layer 312, and a conductive film obtained by processing the same conductive film as the conductive layer 326. End portions of the conductive layer 323 are covered with the sacrifice layer 318, the insulating layer 325, and the insulating layer 327. The layer 314 is provided over the conductive layer 323, and the common electrode 315 is provided over the layer 314. The conductive layer 323 and the common electrode 315 are connected to each other through the layer 314. Note that the layer 314 is not necessarily formed in the connection portion 340. In this case, the conductive layer 323 and the common electrode 315 are directly in contact with each other.

The display apparatus 300A has a top emission structure, for example. Light L from the light-emitting device is emitted toward the substrate 352. For the substrate 352, a material having a high visible-light-transmitting property is preferably used. The pixel electrode contains a material reflecting visible light, and the counter electrode (the common electrode 315) contains a material transmitting visible light. Note that the display apparatus may have a bottom-emission structure.

An insulating layer 220 is provided to cover the transistors. The insulating layer 324 is provided to cover the transistors and has a function of a planarization layer. Note that there is no limitation on the number of insulating layers covering the transistors, and either a single layer or two or more layers may be employed.

A material through which impurities such as water and hydrogen are not easily diffused is preferably used for at least one of the insulating layers covering the transistors. This is because such an insulating layer can function as a barrier layer. Such a structure can effectively inhibit diffusion of impurities into the transistors from the outside and increase the reliability of the display apparatus.

As the insulating layer 220, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating film can be suitably used for the insulating layer 324 functioning as the planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A connection portion 204 is provided in a region of the substrate 351 not overlapping with the substrate 352. In the connection portion 204, the wiring 365 is connected to the FPC 372 through a conductive layer 366 and a connection layer 203. An example is illustrated in which the conductive layer 366 has a stacked-layer structure of a conductive film obtained by processing the same conductive film as the conductive layer 311, a conductive film obtained by processing the same conductive film as the conductive layer 312, and a conductive film obtained by processing the same conductive film as the conductive layer 326. On the top surface of the connection portion 204, the conductive layer 366 is exposed. Thus, the connection portion 204 and the FPC 372 can be connected to each other through the connection layer 203.

A light-blocking layer 317 is preferably provided on the surface of the substrate 352 on the substrate 351 side. The light-blocking layer 317 can be provided between adjacent light-emitting devices 330, in the connection portion 340, in the gate line driver circuit 364, and the like. A variety of optical members can be arranged on the outer surface of the substrate 352. Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 352.

Providing the protective layer 331 that covers the light-emitting device 330 can inhibit entry of impurities such as water into the light-emitting device 330, thereby increasing the reliability of the light-emitting devices.

For each of the substrates 351 and 352, glass, quartz, ceramics, sapphire, a resin, a metal, an alloy, a semiconductor, or the like can be used. The substrate through which light from the light-emitting devices is extracted is formed using a material that transmits the light. When the substrates 351 and 352 are formed using a flexible material, the flexibility of the display apparatus can be increased. Furthermore, a polarizing plate may be used as the substrate 351 or the substrate 352.

For each of the substrates 351 and 352, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrate 351 and the substrate 352.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

For the resin layer 342, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin may be used. An adhesive sheet or the like may be used.

As the connection layer 203, an anisotropic conductive film (ACF), an anisotropic conductive paste (ACP), or the like can be used.

The layer 301 including the transistors is provided between the substrate 351 and the insulating layer 220. The layer 301 includes the transistor 201 and the transistor 202. The transistor 201 is the OS transistor described in Embodiment 1, for example. The transistor 202 is the LTPS transistor described in Embodiment 1, for example. The transistors 201 and 202 are formed over the substrate 351. The transistors 201 and 202 can be manufactured using the same materials in the same steps.

FIG. 29B is an enlarged view of a cross-section of the transistor 201. FIG. 29C is an enlarged view of a cross-section of the transistor 202. As described in Embodiment 1, in one embodiment of the present invention, an OS transistor that is an n-channel transistor and an LTPS transistor that is a p-channel transistor are used as the transistors included in the gate line driver circuit 364. The transistor 201 illustrated in FIG. 29B can be an n-channel transistor, and the transistor 202 illustrated in FIG. 29C can be a p-channel transistor.

The transistor 201 includes an insulating layer 211, a conductive layer 212A, an insulating layer 213, an insulating layer 214, a semiconductor layer 215, an insulating layer 216, a conductive layer 217, an insulating layer 218, and conductive layers 219a and 219b, which are stacked in this order over the substrate 351. Parts of the insulating layer 213, the insulating layer 214, and the insulating layer 218 function as gate insulating layers of the transistor 201. The conductive layer 212A functions as a bottom gate electrode of the transistor 201. The conductive layer 217 functions as a top gate electrode of the transistor 201. The conductive layers 219a and 219b functions as a source electrode and a drain electrode.

The semiconductor layer 215 contains a metal oxide such as an In—Ga—Zn oxide. The conductive layer 219a and the conductive layer 219b are connected to low-resistance regions 215n included in the semiconductor layer 215 through opening portions provided in the insulating layer 216 and the insulating layer 218. The low-resistance regions 215n can also be regarded as a region having lower resistance than the channel formation region of the transistor 201, a region having a higher carrier concentration than the channel formation region, a region having a higher density of oxygen vacancy than the channel formation region, a region having a higher impurity concentration than the channel formation region, or an n-type region. For example, the low-resistance regions 215n contain an impurity element. Examples of the impurity element include hydrogen, boron, carbon, nitrogen, fluorine, phosphorus, sulfur, arsenic, aluminum, and a noble gas. Typical examples of the noble gas include helium, neon, argon, krypton, and xenon. In particular, the low-resistance regions 215n preferably contain boron or phosphorus. The low-resistance regions 215n may contain two or more of the above elements.

The transistor 202 includes a semiconductor layer 210, the insulating layer 211, a conductive layer 212B, the insulating layer 213, the insulating layer 214, the insulating layer 216, the insulating layer 218, and conductive layers 219c and 219d, which are stacked over the substrate 351 in this order. Part of the insulating layer 211 functions as a gate insulating layer of the transistor 202. The conductive layer 212B functions as a top gate electrode of the transistor 202. The conductive layers 219c and 219d function as a source electrode and a drain electrode.

The semiconductor layer 210 contains silicon such as low-temperature polysilicon. The conductive layer 219c and the conductive layer 219d are connected to low-resistance regions 210p included in the semiconductor layer 210 through opening portions provided in the insulating layer 211, the insulating layer 213, the insulating layer 214, the insulating layer 216, and the insulating layer 218. The low-resistance regions 210p can also be regarded as a region having lower resistance than the channel formation region of the transistor 202, a region having a higher impurity concentration than the channel formation region, or a p-type region. For example, the low-resistance regions 210p are regions containing an impurity element for forming a p-channel transistor. Boron and/or aluminum is added to the low-resistance regions 210p to form a p-channel transistor. Moreover, in order to control the threshold voltage of the transistor 202, the above-described impurity may be added to the channel formation region of the transistor 202.

The components of the transistors 201 and 202 other than the semiconductor layers can be concurrently formed in the same process. This can inhibit an increase in the number of steps even when two types of transistors are incorporated.

As materials for a gate electrode, a source electrode, and a drain electrode of a transistor and conductive layers functioning as wirings and electrodes included in the display apparatus, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium; or an alloy material containing any of these metal materials. Alternatively, a nitride of the metal material (e.g., titanium nitride) or the like may be used. The metal material or the alloy material (or the nitride thereof) is made thin enough to have a light-transmitting property to be used. Alternatively, a stacked film of any of the above materials can be used for the conductive layers. For example, a stacked film of indium tin oxide and an alloy of silver and magnesium is preferably used because conductivity can be increased. They can also be used for conductive layers such as wirings and electrodes included in the display apparatus, and conductive layers (e.g., a conductive layer functioning as a pixel electrode or a common electrode) included in a light-emitting device.

Examples of insulating materials that can be used for the insulating layers include a resin such as an acrylic resin and an epoxy resin, and an inorganic insulating material such as silicon oxide, silicon oxynitride, silicon nitride oxide, silicon nitride, and aluminum oxide.

Note that in FIG. 29B, the conductive layer 217 functioning as a top gate electrode can be omitted. FIG. 30A is a schematic cross-sectional view of a display apparatus 300A_1 including a transistor 201A in which the conductive layer 217 functioning as a top gate electrode is omitted, for example. FIG. 30B is an enlarged view of a cross section including the transistor 201A illustrated in FIG. 30A. Note that the display apparatus 300A_1 and the transistor 201A have many portions in common with the display apparatus 300A and the transistor 201 described with reference to FIGS. 29A and 29B; thus, detailed description thereof is omitted.

FIG. 31 is a plan view illustrating the case where the transistor 201A and the transistor 202 illustrated in FIG. 29C and FIGS. 30A and 30B are used in the unit circuit included in the gate line driver circuit 364, e.g., the unit circuit 100G described in Embodiment 1. FIG. 31 is an example of a plan view of the unit circuit 100G and is not limited thereto.

FIG. 31 illustrates the unit circuit 100G which performs output to a gate line in the k-th row (k is an integer greater than or equal to 1 and less than or equal to m). In the unit circuit 100G, the transistor Tn1 that is an n-channel OS transistor can be provided with reference to the transistor 201A illustrated in FIG. 30B, and the transistors Tp1 to Tp7 that are p-channel LTPS transistors can be provided with reference to the transistor 202 illustrated in FIG. 29C.

FIG. 31 illustrates the power supply line 103 for transmitting VDD, the power supply line 104 for transmitting VSS, the wiring 101 for transmitting the clock signal CK1, the wiring 102 for transmitting the clock signal CK2, the wiring 106P for transmitting the output signal OUTP, the wiring 106N for transmitting the output signal OUTN, a wiring 105_k−1 for transmitting a signal corresponding to an output signal OUTP_k−1 in the previous stage, and a wiring 105_k for transmitting a signal corresponding to an output signal OUTP_k to the subsequent stage, for example.

FIG. 31 illustrates a conductive layer 401, a conductive layer 402, a semiconductor layer 403, a semiconductor layer 404, a contact hole 405, and a contact hole 406 for forming wirings, transistors, and capacitors, for example. The conductive layer 401 is provided in the same layer as the conductive layers 212A and 212B described with reference to FIGS. 29C and 30B. The conductive layer 402 is provided in the same layer as the conductive layers 219a to 219d illustrated in FIGS. 29C and 30B. The semiconductor layer 403 is provided in the same layer as the semiconductor layer 215 illustrated in FIG. 30B. The semiconductor layer 404 is provided in the same layer as the semiconductor layer 210 illustrated in FIG. 29C. The contact hole 405 is an opening portion for connecting the conductive layer 401 and the conductive layer 402. The contact hole 406 is an opening portion for connecting the conductive layer 402 and the semiconductor layer 215 (or the semiconductor layer 210).

In the plan view illustrated in FIG. 31, the transistor 201A in which the conductive layer 217 functioning as a top gate electrode is omitted is used as the transistor Tn1. Thus, the process of providing the conductive layer 217 can be omitted, and the yield is expected to be improved.

In FIG. 31, the conductive layer 401 and the conductive layer 402 overlap with each other with an insulating layer therebetween to form the capacitor Cp. Note that in a region other than the region where the capacitor Cp is provided, the cross-over capacitance of the wirings may increase due to the overlap of the conductive layer 401 and the conductive layer 402. Therefore, it is preferable to provide a notch portion in the conductive layers to reduce the cross-over capacitance of the wirings. With this structure, noise to a transmitted signal can be reduced, and signal delay or waveform distortion can be reduced.

In FIG. 31, the power supply lines 103 and 104 that respectively transmit VDD and VSS are preferably provided on the outer side of the wirings 101 and 102 (on the side far from the transistors Tn1 and Tp1 to Tp8) that respectively transmit the clock signals CK1 and CK2. With this structure, the cross-over capacitance of the wirings 101 and 102 that respectively transmit the clock signals CK1 and CK2 and the power supply lines 103 and 104 that respectively transmit VDD and VSS can be reduced. With this structure, noise to a transmitted signal can be reduced, and signal delay or waveform distortion can be reduced.

In FIG. 31, the area where the conductive layer 401 and the semiconductor layer 215 (or the semiconductor layer 210) overlap with each other is preferably larger in the transistors Tp1 and Tp2 than in the transistors Tn1 and Tp3 to Tp7. With this structure, the channel width of the transistor can be increased, and thus the amount of current flowing through the transistor can be increased. Accordingly, high-speed charging and discharging of the wiring that transmits the output signal OUTP having a large load can be achieved.

Note that as described in Embodiment 1, the loads driven by the transistors Tp1 and Tp2 are larger than the loads driven by the transistors Tp3, Tp4, Tp5, Tp6, Tp7, and Tp8 in the unit circuit. Therefore, as illustrated in FIG. 31, the W (channel width)/L (channel length) of the transistors Tp1 and Tp2 is preferably higher than that of the transistors Tp3, Tp4, Tp5, Tp6, Tp7, and Tp8. The W (channel width)/L (channel length) can be calculated from the area of a region where the semiconductor layer 404 and the conductive layer 401 overlap with each other as illustrated in FIG. 31.

Note that in FIG. 29B, the conductive layer 212A functioning as a bottom gate electrode can be omitted. FIG. 32A is a schematic cross-sectional view of a display apparatus 300A_2 including a transistor 201B in which the conductive layer 212A functioning as a bottom gate electrode is omitted, for example. FIG. 32B is an enlarged view of a cross section including the transistor 201B illustrated in FIG. 32A. Note that the display apparatus 300A_2 and the transistor 201B have many portions in common with the display apparatus 300A and the transistor 201 described with reference to FIGS. 29A and 29B; thus, detailed description thereof is omitted.

FIG. 33 is a plan view illustrating the case where the transistor 201B and the transistor 202 illustrated in FIG. 29C and FIGS. 32A and 32B are used in the unit circuit included in the gate line driver circuit 364, e.g., the unit circuit 100G described in Embodiment 1. FIG. 33 is an example of a plan view of the unit circuit 100G and is not limited thereto. Note that in the description of the plan view illustrated in FIG. 33, description of structures common to that in the plan view illustrated in FIG. 32 is omitted. The display apparatus 300A_2 and the transistor 201B have many portions in common with the display apparatus 300A and the transistor 201 described with reference to FIGS. 29A and 29B; thus, detailed description thereof is omitted.

FIG. 33 illustrates a unit circuit 100G_2 which performs output to the gate line in the k-th row. In the unit circuit 100G_2, the transistor Tn1 that is an n-channel OS transistor can be provided with reference to the transistor 201B illustrated in FIG. 32B, and the transistors Tp1 to Tp7 that are p-channel LTPS transistors can be provided with reference to the transistor 202 illustrated in FIG. 29C.

FIG. 33 illustrates the conductive layer 401, the conductive layer 402, the semiconductor layer 403, the semiconductor layer 404, the contact hole 405, the contact hole 406, a conductive layer 407, and a contact hole 408 for forming wirings, transistors, and capacitors, for example. The conductive layer 401 is provided in the same layer as the conductive layer 212B illustrated in FIG. 29C. The conductive layer 402 is provided in the same layer as the conductive layers 219a to 219d illustrated in FIGS. 29C and 32B. The semiconductor layer 403 is provided in the same layer as the semiconductor layer 215 illustrated in FIG. 32B. The semiconductor layer 404 is provided in the same layer as the semiconductor layer 210 illustrated in FIG. 29C. The contact hole 405 is an opening portion for connecting the conductive layer 401 and the conductive layer 402. The contact hole 406 is an opening portion for connecting the conductive layer 402 and the semiconductor layer 215 (or the semiconductor layer 210). The conductive layer 407 is provided in the same layer as the conductive layer 217 illustrated in FIG. 32B. The contact hole 408 is an opening portion for connecting the conductive layer 402 and the conductive layer 407.

In a plan view of a unit circuit 100G_A illustrated in FIG. 33, the transistor 201B in which the conductive layer 212A functioning as a bottom gate electrode is omitted is used as the transistor Tn1. Thus, wirings can be connected using the conductive layer 407 and an element such as a capacitor can be provided. For example, in the capacitor Cp illustrated in FIG. 33, the conductive layer 402 and the conductive layer 407 are provided with an insulating layer (corresponding to the insulating layer 216 illustrated in FIG. 32B) interposed therebetween. The insulating layer of the capacitor Cp is an insulating layer corresponding to a gate insulating film of the transistor 201B. Thus, a capacitor can be provided using an insulating layer with a small thickness. As a result, the area occupied by the capacitor Cp, noise to a transmitted signal, and signal delay or waveform distortion of can be reduced.

Note that as described in Embodiment 1, the load driven by the transistor Tp1 is larger than the load driven by the transistor Tp2 in the unit circuit. Therefore, the W/L of the transistor Tp1 is preferably higher than that of the transistor Tp2. For example, as in a plan view of a unit circuit 100G B illustrated in FIG. 34, the W (channel width)/L (channel length) of the transistor Tp1 is preferably higher than that of the transistor Tp2. The W (channel width)/L (channel length) can be calculated from the area of the region where the semiconductor layer 404 and the conductive layer 401 overlap with each other as illustrated in FIG. 34.

Note that as described in Embodiment 1, the mobility of the transistor Tn1 is smaller than the mobility of the transistors Tp1 to Tp7 in the unit circuit. Therefore, the W/L of the transistor Tn1 is preferably higher than that of the transistors Tp1 to Tp7. For example, as in a plan view of a unit circuit 100G_C illustrated in FIG. 35, the W (channel width)/L (channel length) of the transistor Tn1 is preferably higher than that of the transistors Tp3 to Tp7. The W (channel width)/L (channel length) can be calculated from the area of a region where the semiconductor layer 403 and the conductive layer 401 overlap with each other as illustrated in FIG. 35.

Note that as described in Embodiment 1, SP supplied to the wiring 105_k−1 is transmitted to the gate of the transistor Tp1 through the transistors Tp3 and Tp4 in the unit circuit. Therefore, increasing the drive capability of the transistor Tp3 and the transistor Tp4 can improve the operating speed. Therefore, the W/L of the transistors Tp3 and Tp4 is preferably higher than that of the transistors Tp5 to Tp7. For example, as in a plan view of a unit circuit 100G_D illustrated in FIG. 36, the W (channel width)/L (channel length) of the transistors Tp3 and Tp4 is preferably higher than that of the transistors Tp5 to Tp7. The W (channel width)/L (channel length) can be calculated from the area of the region where the semiconductor layer 404 and the conductive layer 401 overlap with each other as illustrated in FIG. 36.

Although the transistor 201 and the transistor 202 are provided in each of the gate line driver circuit 364 and the display portion 362 in FIGS. 29A, 30A, and 32A, only the transistors 201 or the transistors 202, that is, transistors having the same structure may be used as the transistors included in the display portion 362.

For example, an LTPS transistor such as the transistor 202 is preferably used as all of the transistors included in the pixel circuit of the display portion 362 driving the light-emitting device. As silicon used for a semiconductor layer included in the LTPS transistor, single crystal silicon, polycrystalline silicon, amorphous silicon, or the like can be used as well as low-temperature polysilicon. The LTPS transistor is particularly preferable because of having high field-effect mobility and excellent frequency characteristics.

Note that an OS transistor such as the transistor 201 is preferably used as at least one of the transistors included in the pixel circuit of the display portion 362 driving the light-emitting device. An OS transistor has much higher field-effect mobility than a transistor including amorphous silicon. In addition, an OS transistor has an extremely low off-state current, and charge accumulated in a capacitor that is connected in series to the transistor can be held for a long time. Furthermore, the power consumption of the display apparatus can be reduced with an OS transistor.

When an LTPS transistor is used as one or more of the transistors included in the pixel circuit and an OS transistor is used as the rest, the display apparatus can have low power consumption and high driving capability. In a favorable example, it is preferable that an OS transistor be used as a transistor functioning as a switch for controlling electrical continuity between wirings and an LTPS transistor be used as a transistor for controlling current, for instance.

For example, one of the transistors included in the pixel circuit functions as a transistor for controlling current flowing through the light-emitting device and can be referred to as a driving transistor. One of a source and a drain of the driving transistor is connected to the pixel electrode of the light-emitting device. An LTPS transistor is preferably used as the driving transistor. In that case, the amount of current flowing through the light-emitting device can be increased in the pixel circuit.

Another transistor included in the pixel circuit functions as a switch for controlling selection and non-selection of the pixel and can be referred to as a selection transistor. A gate of the selection transistor is connected to a gate line, and one of a source and a drain thereof is connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

### <Block Diagram of Display Apparatus>

FIG. 37A is a block diagram illustrating the display apparatus 300A. The display apparatus 300A includes the display portion 362, the gate line driver circuit 364, the IC 373, and the like.

The display portion 362 includes a plurality of pixels 363 arranged in a matrix. The pixel 363 includes a subpixel 370R, a subpixel 370G, and a subpixel 370B. The subpixels 370R, 370G, and 370B each include a light-emitting device functioning as a display device.

The pixel 363 is connected to a wiring GL, a wiring SLR, a wiring SLG, and a wiring SLB. The wiring SLR, the wiring SLG, and the wiring SLB are connected to the IC 373. The wiring GL is connected to the gate line driver circuit 364. The wiring GL is a wiring to which the output signal OUT described in Embodiment 1 is outputted. The IC 373 functions as a source line driver circuit (also referred to as a source driver), and the gate line driver circuit 364 functions as a gate line driver circuit (also referred to as a gate driver). The wiring GL functions as a gate line, and the wirings SLR, SLG, and SLB function as source lines.

The subpixel 370R includes a light-emitting device that emits red light. The subpixel 370G includes a light-emitting device that emits green light. The subpixel 370B includes a light-emitting device that emits blue light. Thus, the display apparatus 300A can perform full-color display. Note that the pixel 363 may include a subpixel including a light-emitting device that emits light of another color. For example, the pixel 363 may include, in addition to the three subpixels, a subpixel including a light-emitting device emitting white light or a subpixel including a light-emitting device emitting yellow light.

The wiring GL is connected to the subpixels 370R, 370G, and 370B arranged in the row direction (the extending direction of the wiring GL). The wiring SLR, the wiring SLG, and the wiring SLB are respectively connected to the subpixels 370R, the subpixels 370G, and the subpixels 370B (not illustrated) arranged in the column direction (the extending direction of the wiring SLR and the like).

FIG. 37B illustrates an example of a circuit diagram of the pixel 370 that can be used as the subpixel 370R, the subpixel 370G, and the subpixel 370B. The pixel 370 includes a transistor M1, a transistor M2, a transistor M3, a capacitor C1, and a light-emitting device EL. The wiring GL and a wiring SL are connected to the pixel 370. The wiring SL corresponds to any of the wiring SLR, the wiring SLG, and the wiring SLB illustrated in FIG. 37A.

A gate of the transistor M1 is connected to the wiring GL, one of a source and a drain of the transistor M1 is connected to the wiring SL, and the other of the source and the drain of the transistor M1 is connected to one electrode of the capacitor C1 and a gate of the transistor M2. One of a source and a drain of the transistor M2 is connected to a wiring AL, and the other of the source and the drain of the transistor M2 is connected to one electrode of the light-emitting device EL, the other electrode of the capacitor C1, and one of a source and a drain of the transistor M3. A gate of the transistor M3 is connected to the wiring GL, and the other of the source and the drain of the transistor M3 is connected to a wiring RL. The other electrode of the light-emitting device EL is connected to a wiring CL.

A data potential D is supplied to the wiring SL. A selection signal is supplied to the wiring GL. The selection signal includes a potential for turning on a transistor and a potential for turning off the transistor.

A reset potential is supplied to the wiring RL. An anode potential is supplied to the wiring AL. A cathode potential is supplied to the wiring CL. In the pixel 370, the anode potential is higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistors M1 and M3 function as switches. The transistor M2 functions as a transistor for controlling current flowing through the light-emitting device EL. For example, the transistor M1 can be regarded as functioning as a selection transistor and the transistor M2 as a driving transistor.

Here, it is preferable to use LTPS transistors as all of the transistors M1 to M3. Alternatively, it is preferable to use OS transistors as the transistor M1 and the transistor M3 and to use an LTPS transistor as the transistor M2. Alternatively, it is preferable to use OS transistors as all the transistors M1 to M3.

An OS transistor can achieve extremely low off-state current. Therefore, owing to the low off-state current, charge accumulated in a capacitor that is connected in series to the transistor can be retained for a long time. Hence, it is preferable to use transistors containing an oxide semiconductor as, especially, the transistors M1 and M3 connected in series to the capacitor C1. The use of the transistors containing an oxide semiconductor as the transistors M1 and M3 can prevent leakage of charge held in the capacitor C1 through the transistor M1 or the transistor M3. Furthermore, since charge retained in the capacitor C1 can be retained for a long time, a still image can be displayed for a long time without rewriting data in the pixel 370.

Although the transistors M1 to M3 are n-channel transistors in FIG. 37B, p-channel transistors can also be used. For example, a transistor that allows current to flow current to the light-emitting device EL can be a p-channel transistor and the other transistors can be n-channel transistors.

A transistor including a pair of gates overlapping with a semiconductor layer therebetween can be used as the transistor included in the pixel 370. In the transistor including a pair of gates, the same potential is supplied to the pair of gates connected to each other, whereby the on-state current of the transistor can be increased and the saturation characteristics can be improved. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be connected to a wiring to which a constant potential is supplied or may be connected to a source or a drain of the transistor.

FIG. 37C illustrates an example of the pixel 370 in which a transistor including a pair of gates is used as each of the transistors M1 and M3. The pair of gates of each of the transistors M1 and M3 are connected to each other. Such a structure makes it possible to shorten the period in which data is written to the pixel 370.

FIG. 37D illustrates an example of the pixel 370 in which a transistor including a pair of gates is used as the transistor M2 in addition to the transistors M1 and M3. The pair of gates of the transistor M2 are connected to each other. The transistor M2 having such a structure enables the saturation characteristics to be improved, whereby the luminance of the light-emitting device EL can be easily controlled and the display quality can be increased.

FIG. 38A is a block diagram illustrating a display apparatus 300B that is different from the display apparatus in FIG. 37A. The display apparatus 300B includes the display portion 362, the gate line driver circuit 364, a light-emission control driver circuit 384, the IC 373, and the like. Note that in FIG. 38A, components common to those in FIG. 37A are denoted by the same reference numerals, and the description thereof is omitted.

The display portion 362 includes the plurality of pixels 363 arranged in a matrix. The pixel 363 includes a subpixel 371R, a subpixel 371G, and a subpixel 371B. The subpixel 371R, the subpixel 371G, and the subpixel 371B each include a light-emitting device functioning as a display device.

The pixel 363 is connected to a wiring GLP, a wiring GLN, a wiring EMI, the wiring SLR, the wiring SLG, and the wiring SLB. The gate line driver circuit 364 includes the unit circuit 100G described in Embodiment 1. As illustrated in FIG. 38B, the wirings GLP and GLN are wirings to which output signals OUTP and OUTN outputted from the unit circuit 100G described in Embodiment 1 are supplied. The light-emission control driver circuit 384 outputs a timing signal for controlling light emission of the light-emitting device in the subpixel 371R, the subpixel 371G, and the subpixel 371B. The wiring EMI transmits the timing signal for controlling light emission of the light-emitting device.

FIG. 38C illustrates an example of a circuit diagram of a pixel 371 that can be used as the subpixel 371R, the subpixel 371G, and the subpixel 371B. The pixel 371 includes transistors M11 to M17, a capacitor C2, and the light-emitting device EL. A wiring GLP_k, a wiring GLP_k−1, a wiring GLN_k, the wiring EMI_k, an initializing line INI, and the wiring SL are connected to the pixel 371. The wiring SL corresponds to any of the wiring SLR, the wiring SLG, and the wiring SLB shown in FIG. 38A.

The transistors M11 to M14 are p-channel transistors using LTPS transistors or the like. The transistor M15 is an n-channel transistor using an OS transistor or the like. The transistors M11 to M17, the capacitor C2, and the light-emitting device EL are connected as illustrated in FIG. 38C.

The data potential D is supplied to the wiring SL. A selection signal for selecting a p-channel transistor is supplied to the wiring GLP. A selection signal for selecting an n-channel transistor is supplied to the wiring GLN. An initialization potential is supplied to the initializing line INI. The unit circuit 100G described in Embodiment 1 can output signals for selecting transistors with different polarities. Thus, transistors with different polarities can be selected at different timings in the pixel 371 in FIG. 38C that includes the p-channel transistor and the n-channel transistor. As a result, a plurality of unit circuits for outputting selection signals at different timings do not need to be provided, which enables reduction of the circuit area and power consumption.

In addition, in the display apparatus 300B, both the pixel 371 included in the display portion 362 and the unit circuit 100G included in the gate line driver circuit 364 can have a circuit structure where a p-channel transistor using an LTPS transistor or the like and an n-channel transistor using an OS transistor or the like are used. Thus, the transistors in the display portion 362 and the gate line driver circuit 364 can be manufactured in a common process, which leads to reduction in manufacturing cost.

This embodiment can be combined with any of the other embodiments as appropriate.

### Embodiment 3

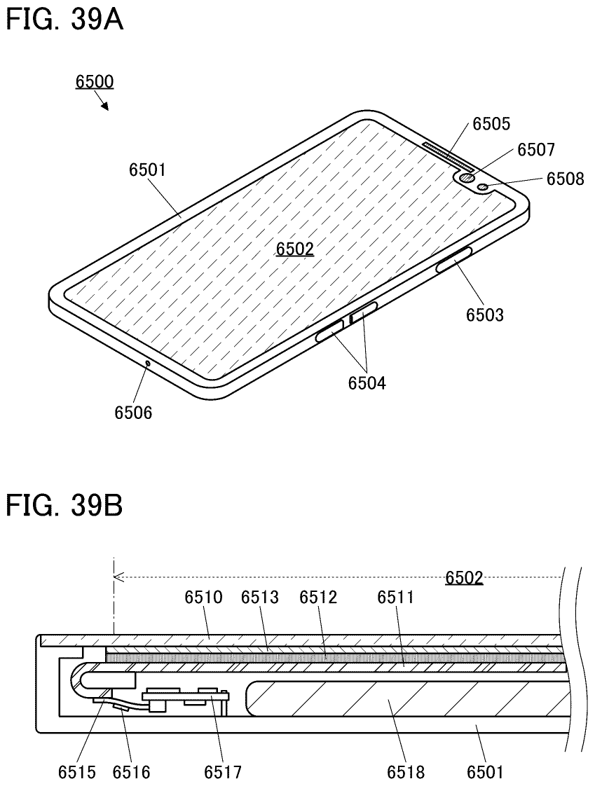

In this embodiment, electronic devices of one embodiment of the present invention will be described with reference to FIGS. 39A and 39B, FIGS. 40A to 40D, and FIGS. 41A to 41G. Electronic devices of this embodiment are each provided with the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer or the like, digital signage, and a large game machine such as a pachinko machine.

An electronic device 6500 illustrated in FIG. 39A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 39B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used for the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

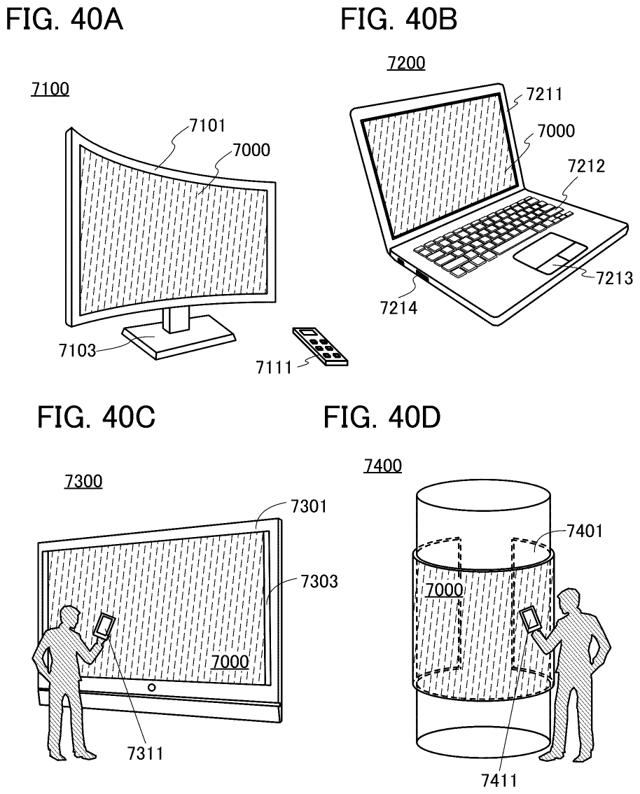

FIG. 40A illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

Operation of the television device 7100 illustrated in FIG. 40A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information outputted from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 40B illustrates an example of a laptop personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000.

FIGS. 40C and 40D illustrate examples of digital signage.

A digital signage 7300 illustrated in FIG. 40C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 40D illustrates digital signage 7400 attached to a cylindrical pillar 7401. The digital signage 7400 includes the display portion 7000 provided along a curved surface of the pillar 7401.

In FIGS. 40C and 40D, the display apparatus of one embodiment of the present invention can be used in the display portion 7000.

A larger area of the display portion 7000 allows a larger amount of information to be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 40C and 40D, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

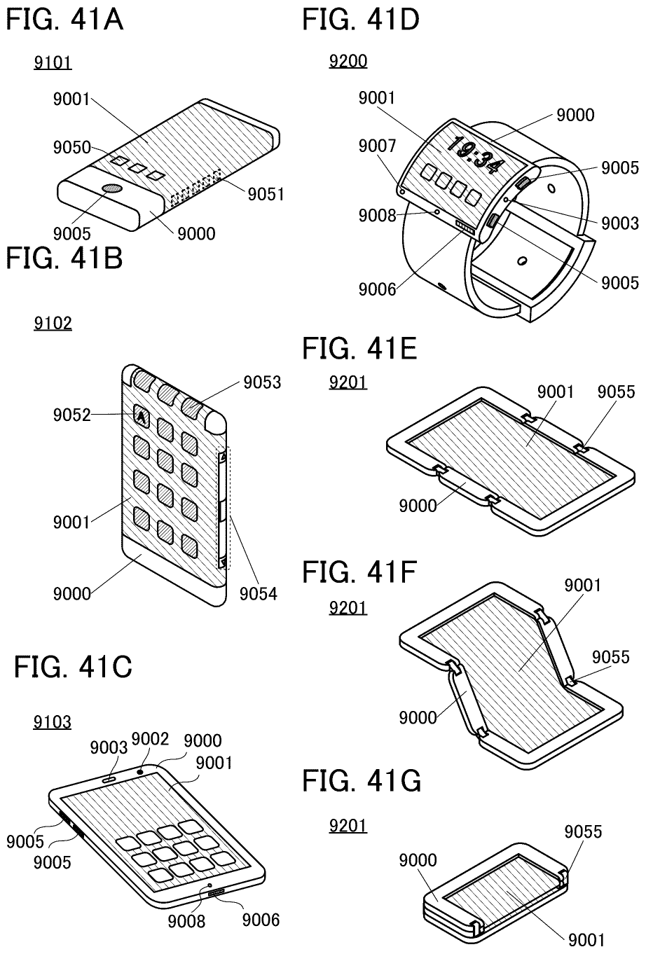

Electronic devices illustrated in FIGS. 41A to 41G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 41A to 41G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, a function of reading out and processing a program or data stored in a recording medium, and the like. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 41A to 41G are described in detail below.

FIG. 41A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 41A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 41B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 41C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 41D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 41E to 41G are perspective views of a foldable portable information terminal 9201. FIG. 41E is a perspective view illustrating the portable information terminal 9201 that is opened. FIG. 41G is a perspective view illustrating the portable information terminal 9201 that is folded. FIG. 41F is a perspective view illustrating the portable information terminal 9201 that is shifted from one of the states in FIGS. 41E and 41G to the other. The portable information terminal 9201 is highly portable when folded. When the portable information terminal 9201 is opened, a seamless large display region is highly browsable. The display portion 9001 of the portable information terminal 9201 is supported by three of the housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

### Notes on the Description in this Specification and the Like

The following are notes on the description of the above embodiments and structures in the embodiments.

One embodiment of the present invention can be constituted by appropriately combining the structure described in an embodiment with any of the structures described in the other embodiments. In addition, in the case where a plurality of structure examples are described in one embodiment, the structure examples can be combined as appropriate.

Note that content (or may be part of the content) described in one embodiment may be applied to, combined with, or replaced by different content (or may be part of the different content) described in the embodiment and/or content (or may be part of the content) described in another embodiment or other embodiments.

Note that in each embodiment, a content described in the embodiment is a content described with reference to a variety of diagrams or a content described with text disclosed in this specification.

Note that by combining a diagram (or may be part of the diagram) illustrated in one embodiment with another part of the diagram, a different diagram (or may be part of the different diagram) illustrated in the embodiment, and/or a diagram (or may be part of the diagram) illustrated in another embodiment or other embodiments, much more diagrams can be formed.

In this specification and the like, components are classified on the basis of the functions and shown as blocks independent of each other in block diagrams. However, in an actual circuit or the like, it is difficult to separate components on the basis of the functions, and there is such a case where one circuit is associated with a plurality of functions or a case where a plurality of circuits is associated with one function. Therefore, the segmentation of a block in the block diagrams is not limited by any of the components described in the specification, and can be explained with another term as appropriate.

In drawings, the size, the layer thickness, or the region is determined arbitrarily for description convenience. Therefore, the size, the layer thickness, or the region is not limited to the illustrated scale. Note that the drawings are schematically shown for clarity, and embodiments of the present invention are not limited to shapes, values, or the like shown in the drawings. For example, variation in signal, voltage, or current due to noise or difference in timing can be included.

In this specification and the like, the terms “one of a source and a drain” (or a first electrode or a first terminal) and “the other of the source and the drain” (or a second electrode or a second terminal) are used to describe the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate.

In addition, in this specification and the like, the term such as an “electrode” or a “wiring” does not limit a function of the component. For example, an “electrode” is used as part of a “wiring” in some cases, and vice versa. Moreover, the term “electrode” or “wiring” also includes the case where a plurality of “electrodes” or “wirings” are formed in an integrated manner, for example.

In this specification and the like, voltage and potential can be interchanged with each other as appropriate. The term “voltage” refers to a potential difference from a reference potential. When the reference potential is a ground voltage, for example, “voltage” can be replaced with “potential”. The ground potential does not necessarily mean 0 V. Potentials are relative values, and the potential applied to a wiring or the like is changed depending on the reference potential, in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

In this specification and the like, a switch is in a conduction state (on state) or in a non-conduction state (off state) to determine whether current flows therethrough or not. Alternatively, a switch has a function of selecting and changing a current path.

In this specification and the like, the channel length refers to, for example, the distance between a source and a drain in a region where a semiconductor (or a portion where current flows in a semiconductor when a transistor is on) and a gate overlap with each other, or a region where a channel is formed in a plan view of the transistor.

In this specification and the like, the channel width refers to, for example, the length of a portion where a source and a drain face each other in a region where a semiconductor (or a portion where current flows in a semiconductor when a transistor is on) and a gate electrode overlap each other, or a region where a channel is formed.

In this specification and the like, an “on state” of a transistor refers to a state in which a source and a drain of the transistor are short-circuited, for example. The “on state” refers to the state of an n-channel transistor where the voltage between its gate and source is higher than the threshold voltage or the state of a p-channel transistor where the voltage between its gate and source is lower than the threshold voltage, for example. Note that an “on state” of a transistor is a state where current can flow between a source and a drain. Thus, the “on state” of a transistor refers to a “conduction state” of the transistor in some cases.

In this specification and the like, an “off state” of a transistor refers to a state in which a source and a drain of the transistor are disconnected. The “off state” refers to the state of an n-channel transistor where the voltage between its gate and source is lower than the threshold voltage or the state of a p-channel transistor where the voltage between its gate and source is higher than the threshold voltage, for example. Thus, the “off state” of a transistor can be referred to the “non-conduction state” of the transistor in some cases.

In this specification and the like, “gate voltage” refers to the voltage between a gate and a source, “drain voltage” refers to the voltage between a drain and a source, and “back gate voltage” refers to the voltage between a back gate and a source in some cases. In addition, “drain current” refers to the current flowing from the drain to the source in some cases.

In this specification and the like, “off-state current” of a transistor refers to drain current of the transistor in the off state unless otherwise specified. Note that off-state current and current that flows from a gate to a source and a drain (also referred to as gate leakage current) are each referred to as leakage current in some cases in this specification and the like.

The expression “connection” in this specification includes “electrical connection”, for example.

When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example.

Here, in the case where one embodiment of the present invention is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

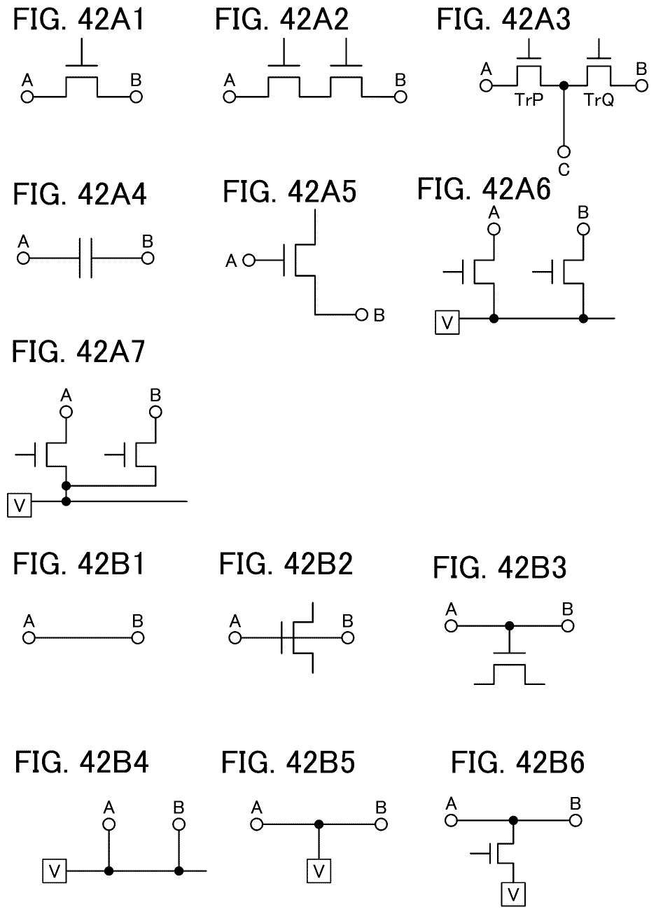

Specific examples of the case of “indirect connection” are described below. First, examples of the case where the expression “A and B are indirectly connected” can be used include the case where A and B are connected to each other through a source and a drain of at least one transistor as in FIG. 42A1 and FIG. 42A2. Another example thereof is the case where A and B are connected to each other with at least one switch therebetween. In the case where the expression “A and B are indirectly connected” can be used, one transistor between A and B is brought into an on state, a conduction state, or a state where current can flow at least once on the assumption that a circuit is in operation. The case where the expression “A and B are indirectly connected” can be used may include a period at which the one transistor between A and B is brought into an off state or a non-conduction state. In the case where the expression “A and B are indirectly connected” can be used, each of a plurality of transistors between A and B is brought into an on state, a conduction state, or a state where current can flow at least once when the plurality of transistors are connected between A and B on the assumption that a circuit is in operation. That is, in the case where the expression “A and B are indirectly connected” can be used, it is not necessary that all of the plurality of transistors be brought into an on state, a conduction state, or a state where current can flow at the same time. Accordingly, in the case where the expression “A and B are indirectly connected” can be used, the plurality of transistors between A and B may be brought into an off state or a non-conduction state at the same time or at different times. As another example, when A and C are connected to each other through a source and a drain of a transistor TrP and B and C are connected to each other through a source and a drain of a transistor TrQ as illustrated in FIG. 42A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the case where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 42A4. Another example thereof is the case where there is a gate insulating film of a transistor or the like between A and B as in FIG. 42A5. In that case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 42A6 and 42A7. In that case, the expression “A and B are indirectly connected” cannot be used; however, the expression “A and V are indirectly connected” or “B and V are indirectly connected” can be used. Note that in FIG. 42A3, when A and C are connected to each other through the source and the drain of the transistor TrP, B and C are connected to each other through the source and the drain of the transistor TrQ, and a constant potential V is supplied to C from a power source, a GND, or the like, the same connection relation as that in FIG. 42A6 and FIG. 42A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 42B1, 42B2, and 42B3. When A and B are connected to a power source, GND, or the like from which a constant potential V is supplied without a circuit element therebetween as in FIGS. 42B4 and 42B5, the expression “A and B are directly connected”, “A and V are directly connected”, or “B and V are directly connected” can be used. Note that when A (or B) is connected to a constant potential V through a source and a drain of a transistor as in FIG. 42B6, the expression “A and B are directly connected” can also be used. Note that A and V or B and V are connected to each other through the source and the drain of the transistor and thus they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus in the case where the expression “A and B are directly connected” is used, the expression “A and B are electrically connected” can also be used.

This application is based on Japanese Patent Application Serial No. 2023-169553 filed with Japan Patent Office on Sep. 29, 2023, the entire contents of which are hereby incorporated by reference.

What is claimed is:

1. A display apparatus comprising a gate line driver circuit,
wherein a unit circuit in the gate line driver circuit comprises first to fifth p-channel transistors and an n-channel transistor,
wherein one of a source and a drain of the first p-channel transistor is electrically connected to a first clock signal line,
wherein one of a source and a drain of the second p-channel transistor is electrically connected to a first power supply line,
wherein the other of the source and the drain of the first p-channel transistor is electrically connected to the other of the source and the drain of the second p-channel transistor,
wherein a gate of the first p-channel transistor is electrically connected to one of a source and a drain of the third p-channel transistor,
wherein the gate of the first p-channel transistor is directly connected to a gate of the n-channel transistor,
wherein a gate of the third p-channel transistor is electrically connected to a second power supply line,
wherein the other of the source and the drain of the third p-channel transistor is electrically connected to one of a source and a drain of the fourth p-channel transistor,
wherein the other of the source and the drain of the third p-channel transistor is electrically connected to a gate of the fifth p-channel transistor,
wherein a gate of the fourth p-channel transistor is electrically connected to a second clock signal line,
wherein one of a source and a drain of the fifth p-channel transistor is electrically connected to the first power supply line,
wherein the other of the source and the drain of the fifth p-channel transistor is electrically connected to a gate of the second p-channel transistor,
wherein the other of the source and the drain of the fifth p-channel transistor is electrically connected to one of a source and a drain of the n-channel transistor, and
wherein the other of the source and the drain of the n-channel transistor is electrically connected to the second power supply line.

2. The display apparatus according to claim 1,
wherein the n-channel transistor comprises a first semiconductor layer, and
wherein the first semiconductor layer comprises an oxide semiconductor.

3. The display apparatus according to claim 1,
wherein the first to fifth p-channel transistors each comprise a second semiconductor layer, and
wherein the second semiconductor layer comprises silicon.

4. A display apparatus comprising a gate line driver circuit,
wherein a unit circuit in the gate line driver circuit comprises first to seventh p-channel transistors and an n-channel transistor,
wherein one of a source and a drain of the first p-channel transistor is electrically connected to a first clock signal line,
wherein one of a source and a drain of the second p-channel transistor is electrically connected to a first power supply line,
wherein the other of the source and the drain of the first p-channel transistor is electrically connected to the other of the source and the drain of the second p-channel transistor,
wherein a gate of the first p-channel transistor is electrically connected to one of a source and a drain of the third p-channel transistor,
wherein the gate of the first p-channel transistor is directly connected to a gate of the n-channel transistor,
wherein a gate of the third p-channel transistor is electrically connected to a second power supply line,
wherein the other of the source and the drain of the third p-channel transistor is electrically connected to one of a source and a drain of the fourth p-channel transistor,
wherein the other of the source and the drain of the third p-channel transistor is electrically connected to one of a source and a drain of the sixth p-channel transistor,
wherein the other of the source and the drain of the third p-channel transistor is electrically connected to a gate of the fifth p-channel transistor,
wherein a gate of the fourth p-channel transistor is electrically connected to a second clock signal line,
wherein one of a source and a drain of the fifth p-channel transistor is electrically connected to the first power supply line,
wherein the other of the source and the drain of the fifth p-channel transistor is electrically connected to a gate of the second p-channel transistor,
wherein the other of the source and the drain of the fifth p-channel transistor is electrically connected to a gate of the seventh p-channel transistor,
wherein the other of the source and the drain of the fifth p-channel transistor is electrically connected to one of a source and a drain of the n-channel transistor,
wherein the other of the source and the drain of the n-channel transistor is electrically connected to the second power supply line,
wherein a gate of the sixth p-channel transistor is electrically connected to the first clock signal line,
wherein the other of the source and the drain of the sixth p-channel transistor is electrically connected to one of a source and a drain of the seventh p-channel transistor, and
wherein the other of the source and the drain of the seventh p-channel transistor is electrically connected to the first power supply line.

5. The display apparatus according to claim 4,
wherein the n-channel transistor comprises a first semiconductor layer, and
wherein the first semiconductor layer comprises an oxide semiconductor.

6. The display apparatus according to claim 4,
wherein the first to seventh p-channel transistors each comprise a second semiconductor layer, and
wherein the second semiconductor layer comprises silicon.
